(19) United States
(12) Patent Application Publication
(10) Pub. No.: US 2025/0104635 A1
(43) Pub. Date: Mar. 27, 2025

(54) DISPLAY DEVICE

(71) Applicant: Samsung Display Co., LTD., Yongin-si (KR)

(72) Inventors: DONG HEE SHIN, Yongin-si (KR); SUNKWUN SON, Yongin-si (KR)

(73) Assignee: Samsung Display Co., LTD., Yongin-si (KR)

(21) Appl. No.: 18/893,421

(22) Filed: Sep. 23, 2024

(30) Foreign Application Priority Data
Sep. 27, 2023 (KR) 10-2023-0130100

(51) Int. Cl. G09G 3/3233; G09G 3/32

(52) U.S. Cl. CPC G09G 3/3233; G09G 3/32; G09G 2300/0426; G09G 2320/0209

(57) ABSTRACT

A display device includes a substrate including first to N-th pixel circuit areas, where N is a natural number greater than 1 disposed in a first direction, an initialization voltage line disposed on the substrate, the initialization voltage line extending in a second direction, intersecting the first direction, and overlapping one of the first to N-th pixel circuit areas, a driving voltage line disposed on the substrate, the driving voltage line extending in the second direction, and adjacent to the initialization voltage line in the first direction, and a data line disposed on the substrate, the data line extending in the second direction, and spaced apart from the initialization voltage line in the first direction with the driving voltage line disposed between the data line and the initialization voltage line.

### CROSS-REFERENCE TO RELATED APPLICATION(S)

This application claims priority to and benefits of Korean Patent Application No. 10-2023-0130100 under 35 USC § 119, filed on Sep. 27, 2023, in the Korean Intellectual Property Office, the entire contents of which are incorporated herein by reference.

### BACKGROUND

### 1. Technical Field

The disclosure relates generally to a display device. For example, the disclosure relates to a display device that provides visual information.

### 2. Description of the Related Art

With the development of information technology, the importance of a display device, which is a connection medium between a user and information, has been highlighted. For example, the use of display devices such as liquid crystal display (LCD) device, organic light emitting display (OLED) device, plasma display panel (PDP) device, quantum dot display device or the like is increasing.

A display device may include a pixel that generates light, and the pixel may include a light emitting element. The light emitting element may emit light based on a driving current. As the resolution of the display device increases, parasitic capacitance may be formed between lines included in the pixel. The parasitic capacitance may cause a problem with deterioration of the display quality of the display device, such as visible stains.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device with improved display quality.

A display device according to an embodiment may include a substrate including first to N-th pixel circuit areas, where N is a natural number greater than 1 disposed in a first direction; an initialization voltage line disposed on the substrate, the initialization voltage line extending in a second direction, intersecting the first direction, and overlapping one of the first to N-th pixel circuit areas; a driving voltage line disposed on the substrate, the driving voltage line extending in the second direction, and adjacent to the initialization voltage line in the first direction; and a data line disposed on the substrate, the data line extending in the second direction, and spaced apart from the initialization voltage line in the first direction with the driving voltage line disposed between the data line and the initialization voltage line.

In an embodiment, the display device may further include first to N-th pixel circuits disposed in the first to N-th pixel circuit areas, respectively. Each of the first to N-th pixel circuits may include a driving transistor which provides a driving current, a first switching transistor which provides a data voltage to the driving transistor, and a second switching transistor which provides an initialization voltage to the driving transistor.

In an embodiment, a gate electrode of the first switching transistor and a gate electrode of the second switching transistor may receive a same signal.

In an embodiment, the driving voltage line may overlap each of the first to N-th pixel circuit areas. The driving voltage line overlapping the (N-1)-th pixel circuit area may provide a driving voltage to the driving transistor included in the N-th pixel circuit.

In an embodiment, the display device may further include a common voltage line disposed on the substrate and extending in the second direction. The common voltage line, the driving voltage line, and the data line may be disposed in the first direction in an order of the driving voltage line, the data line, and the common voltage line.

In an embodiment, the driving voltage line and the common voltage line may be disposed in a same layer.

In an embodiment, the driving voltage line and the common voltage line may be disposed in different layers.

In an embodiment, the display device may further include an active pattern disposed on the substrate and overlapping the first to N-th pixel circuit areas, a first conductive layer disposed on the active pattern and including a gate electrode, and a second conductive layer disposed on the first conductive layer.

In an embodiment, the second conductive layer may include the driving voltage line and the common voltage line.

In an embodiment, the display device may further include a third conductive layer disposed on the second conductive layer. The second conductive layer may include the driving voltage line, and the third conductive layer may include the common voltage line.

In an embodiment, the active pattern may include an oxide semiconductor.

A display device according to an embodiment may include a substrate including first to N-th pixel circuit areas, where N is a natural number greater than 1 disposed in a first direction; an initialization voltage line disposed on the substrate, the initialization voltage line extending in a second direction, intersecting the first direction, and overlapping one of the first to N-th pixel circuit areas; a common voltage line disposed on the substrate, the common voltage line extending in the second direction, and adjacent to the initialization voltage line in the first direction; and a data line disposed on the substrate, the data line extending in the second direction, and spaced apart from the initialization voltage line in the first direction with the common voltage line disposed between the data line and the initialization voltage line.

In an embodiment, the display device may further include first to N-th pixel circuits disposed in the first to N-th pixel circuit areas, respectively. Each of the first to N-th pixel circuits may include a driving transistor which provides a driving current, a first switching transistor which provides a data voltage to the driving transistor, and a second switching transistor which provides an initialization voltage to the driving transistor.

In an embodiment, a gate electrode of the first switching transistor and a gate electrode of the second switching transistor may receive a same signal.

In an embodiment, the display device may further include a driving voltage line disposed on the substrate and extending in the second direction. The driving voltage line, the common voltage line, and the data line may be disposed in the first direction in an order of the common voltage line, the data line, and the driving voltage line.

In an embodiment, the driving voltage line may overlap each of the first to N-th pixel circuit areas. The driving voltage line overlapping the N-th pixel circuit area may provide a driving voltage to the driving transistor included in the N-th pixel circuit.

In an embodiment, the driving voltage line and the common voltage line may be disposed on a same layer.

In an embodiment, the display device may further include an active pattern disposed on the substrate and overlapping the first to N-th pixel circuit areas, a first conductive layer disposed on the active pattern and including a gate electrode, and a second conductive layer disposed on the first conductive layer.

In an embodiment, the second conductive layer may include the driving voltage line and the common voltage line.

A display device according to an embodiment may include an initialization voltage line, a driving voltage line adjacent to the initialization voltage line in a first direction, and a data line spaced apart from the initialization voltage line in the first direction with the driving voltage line disposed between the data line and the initialization voltage line.

As the data line is spaced apart from the initialization voltage line in the first direction with the driving voltage line disposed between the data line and the initialization voltage line, the formation of parasitic capacitance between the initialization voltage line and the data line may be reduced. Accordingly, the occurrence of horizontal crosstalk in the display device may be reduced, and the display quality of the display device may be improved.

### BRIEF DESCRIPTION OF THE DRAWINGS

Illustrative, non-limiting embodiments will be more clearly understood from the following detailed description in conjunction with the accompanying drawings in which:

FIG. 1 is a schematic plan view illustrating a display device according to an embodiment.

FIG. 2 is a block diagram illustrating the display device of FIG. 1.

FIG. 3 is a schematic diagram of an equivalent circuit of a pixel for explaining a pixel included in the display device of FIG. 1.

FIG. 4 is a schematic cross-sectional view illustrating the display device of FIG. 1.

FIGS. 5, 6, 7, and 8 are schematic plan views illustrating a pixel included in the display device of FIGS. 1 and 3.

FIG. 9 is a schematic cross-sectional view illustrating a display device according to an embodiment.

FIGS. 10, 11, and 12 are schematic plan views illustrating a pixel included in the display device of FIG. 9.

FIG. 13 is a schematic cross-sectional view illustrating a display device according to an embodiment.

FIGS. 14 and 15 are schematic plan views illustrating a pixel included in the display device of FIG. 13.

### DETAILED DESCRIPTION OF THE EMBODIMENTS

Hereinafter, embodiments will be described in detail with reference to the accompanying drawings. The same reference numerals are used for the same components in the drawings, and redundant descriptions of the same components may be omitted.

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

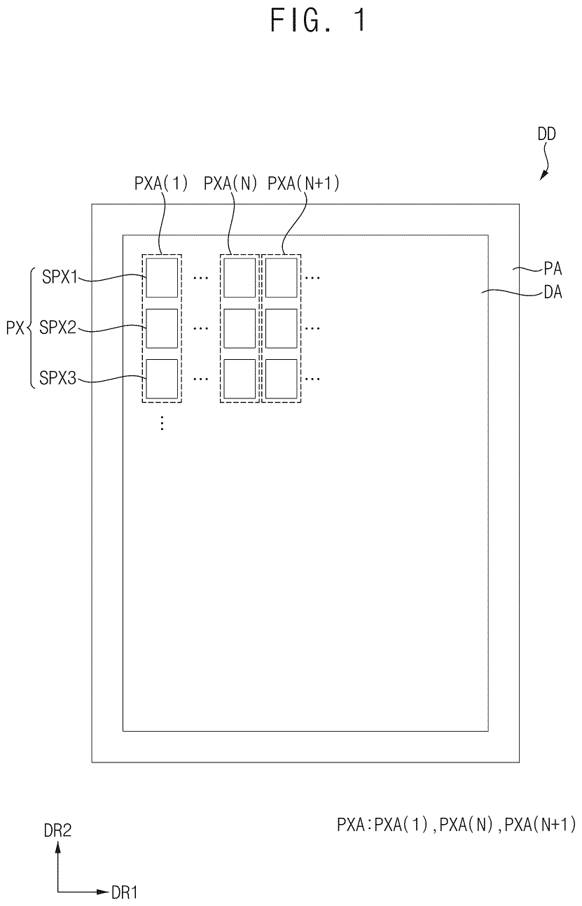

FIG. 1 is a schematic plan view illustrating a display device according to an embodiment.

In this specification, a plane may be defined by a first direction DR1 and a second direction DR2 intersecting the first direction DR1. For example, the first direction DR1 and the second direction DR2 may be perpendicular to each other. A display device DD and various components or layers thereof may have a thickness extended in a third direction which crosses or intersects the plane, for example, each of the first direction DR1 and the second direction DR2.

Referring to FIG. 1, the display device DD according to an embodiment may include a display area DA and a peripheral area PA. The display area DA may be defined as an area that displays an image by generating light or adjusting the transmittance of light provided from an external light source. The peripheral area PA may be positioned around the display area DA. For example, the peripheral area PA may surround at least a portion of the display area DA. The peripheral area PA may be defined as an area that does not display an image.

Pixels PX may be disposed in the display area DA. Each of the pixels PX may generate light according to a driving signal. The pixels PX may be repeatedly arranged or disposed in the first direction DR1 and the second direction DR2. In other words, the pixels PX may be arranged or disposed in rows and columns.

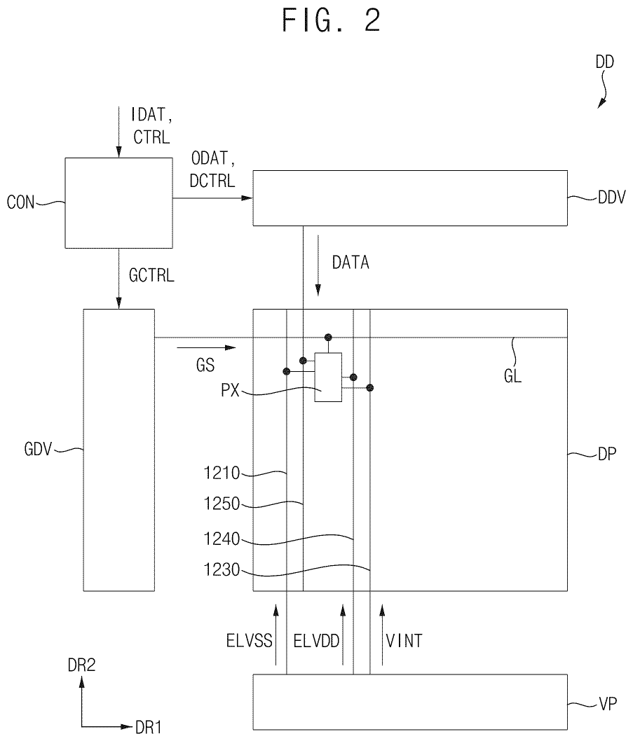

Each of the pixels PX may include a first sub-pixel SPX1, a second sub-pixel SPX2, and a third sub-pixel SPX3. The first sub-pixel SPX1 may generate light of a first color, the second sub-pixel SPX2 may generate light of a second color, and the third sub-pixel SPX3 may generate light of a third color. For example, the first color may be red, the second color may be green, and the third color may be blue. However, the disclosure is not limited thereto. Each of the first sub-pixel SPX1, the second sub-pixel SPX2, and the third sub-pixel SPX3 may be provided with a gate signal GS, a driving voltage ELVDD, a common voltage ELVSS, and an initialization voltage VINT which are illustrated in FIG. 2.

The display area DA may include pixel circuit areas PXA. Each of the pixel circuit areas PXA may include a driving voltage line (for example, a driving voltage line 1240 of FIG. 2), a common voltage line (for example, a common voltage line 1210 of FIG. 2), and a data line (for example, a data line 1250 of FIG. 2), an initialization voltage line (for example, an initialization voltage line 1230 of FIG. 2), etc. For example, the pixel circuit areas PXA may be repeatedly arranged or disposed in the first direction DR1 and the second direction DR2. In other words, the pixel circuit areas PXA may be arranged or disposed in rows and columns. Each of the pixels PX may overlap one of the pixel circuit areas PXA.

In an embodiment, the display area DA may include first to N-th pixel circuit areas arranged or disposed in the first direction DR1. For example, the first pixel circuit area PXA(1) may refer to a pixel circuit area positioned in a first column. The N-th pixel circuit area PXA(N) may refer to a pixel circuit area positioned in an N-th column. The (N+1)-th pixel circuit area PXA(N+1) may refer to the pixel circuit area positioned in an (N+1)-th column. The (N+1)-th pixel circuit area PXA(N+1) and the N-th pixel circuit area PXA(N) may be adjacent to each other in the first direction DR1.

First to N-th pixel circuits may be disposed in the first to N-th pixel circuit areas, respectively. Each of the first to N-th pixel circuits may include a first sub-pixel circuit, a second sub-pixel circuit, and a third sub-pixel circuit. The first sub-pixel circuit may be connected to a light emitting element of the first sub-pixel SPX1. Accordingly, the first sub-pixel circuit may provide a first driving current to the light emitting element of the first sub-pixel SPX1. The second sub-pixel circuit may be connected to a light emitting element of the second sub-pixel SPX2. Accordingly, the second sub-pixel circuit may provide a second driving current to the light emitting element of the second sub-pixel SPX2. The third sub-pixel circuit may be connected to a light emitting element of the third sub-pixel SPX3. Accordingly, the third sub-pixel circuit may provide a third driving current to the light emitting element of the third sub-pixel SPX3.

FIG. 2 is a black diagram illustrating the display device of FIG. 1.

Referring to FIG. 2, the display device DD may include a display panel DP, a data driver DDV, a gate driver GDV, a controller CON, and a voltage supplier VP.

The display panel DP may include the pixels PX. Each of the pixels PX may receive a gate signal GS through a gate line GL. Each of the pixels PX may receive a data voltage DATA through a data line 1250 and receive an initialization voltage VINT through an initialization voltage line 1230. The data voltage DATA may be written to each of the pixels PX in response to the gate signal GS, and the initialization voltage VINT may be written to each of the pixels PX in response to the gate signal GS.

The controller CON may receive an input image data IDAT and a control signal CTRL from an external host processor (for example, graphical processing unit (GPU)). For example, the input image data IDAT may include red image data, green image data, and blue image data. The control signal CTRL may include a vertical synchronization signal, a horizontal synchronization signal, an input data enable signal, a master clock signal, etc. The controller CON may generate a gate control signal GCTRL, a data control signal DCTRL, and an output image data ODAT based on the input image data IDAT and the control signal CTRL.

The data driver DDV may generate the data voltage DATA based on the output image data ODAT and the data control signal DCTRL. For example, the data driver DDV may generate the data voltage DATA corresponding to the output image data ODAT and may output the data voltage DATA to the data line 1250 in response to the data control signal DCTRL. The data control signal DCTRL may include an output data enable signal, a horizontal start signal, and a load signal.

The gate driver GDV may generate the gate signal GS based on the gate control signal GCTRL. The gate driver GDV may output the gate signal GS to the gate line GL. For example, the gate signal GS may include a gate-on voltage that turns on a transistor and a gate-off voltage that turns off the transistor. The gate control signal GCTRL may include a vertical start signal and a gate clock signal.

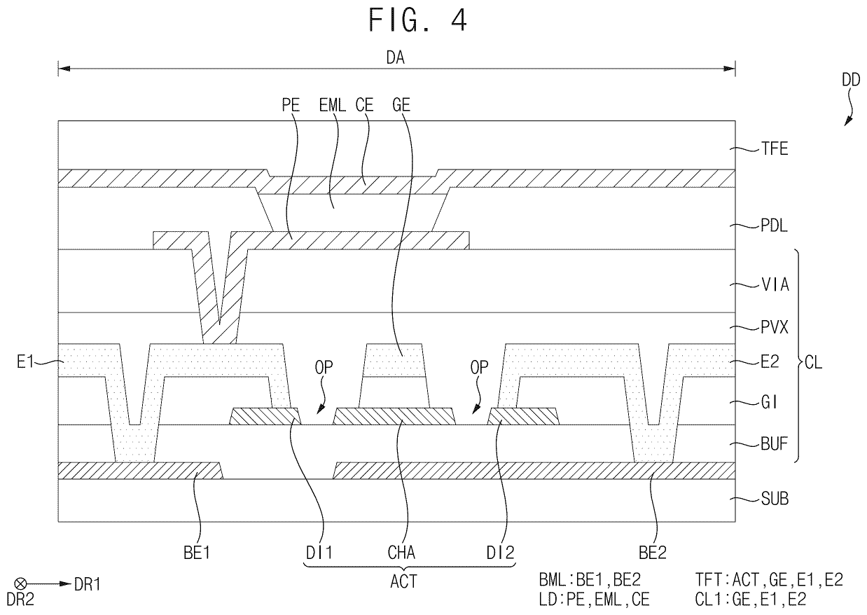

The voltage supplier VP may provide a driving voltage ELVDD, a common voltage ELVSS, and the initialization voltage VINT to each of the pixels PX. The driving voltage ELVDD may be provided to each of the pixels PX through a driving voltage line 1240. The common voltage ELVSS may be provided to each of the pixels PX through a common voltage line 1210 and a common electrode (for example, a common electrode CE of FIG. 4). The initialization voltage VINT may be provided to each of the pixels PX through the initialization voltage line 1230.

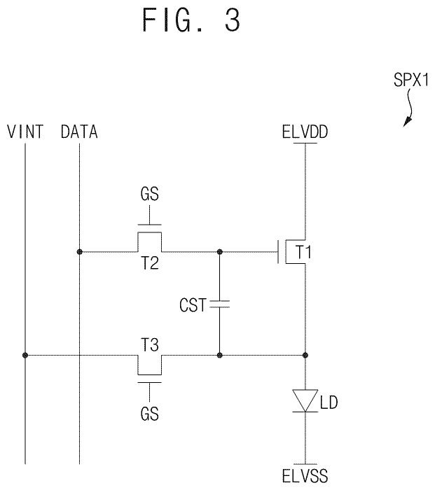

FIG. 3 is a schematic diagram of an equivalent circuit of a pixel for explaining a pixel included in the display device of FIG. 1.

Referring to FIG. 3, the first sub-pixel SPX1 may include the first sub-pixel circuit and a light emitting element LD. The first sub-pixel circuit may include a first transistor T1, a second transistor T2, a third transistor T3, and a storage capacitor CST. The first sub-pixel circuit may provide the first driving current to the light emitting element LD, and the light emitting element LD may generate light based on the first driving current. The second sub-pixel SPX2 and the third sub-pixel SPX3, which are illustrated in FIG. 1, may include substantially the same sub-pixel circuit as the first sub-pixel SPX1. Therefore, the following description will focus on the first sub-pixel SPX1.

The first transistor T1 may include a gate electrode, a first electrode, and a second electrode. The gate electrode of the first transistor T1 may be connected to the second transistor T2. The first electrode of the first transistor T1 may be provided with the driving voltage ELVDD. The second electrode of the first transistor T1 may be connected to the light emitting element LD. The first transistor Tl may generate the first driving current based on the driving voltage ELVDD and the data voltage DATA. For example, the first transistor T1 may be referred to as a driving transistor.

The second transistor T2 may include a gate electrode, a first electrode, and a second electrode. The gate electrode of the second transistor T2 may receive the gate signal GS. The second transistor T2 may be turned on or off in response to the gate signal GS. The first electrode of the second transistor T2 may receive the data voltage DATA. The second electrode of the second transistor T2 may be connected to the first transistor T1. During a period in which the second transistor T2 is turned on, the second transistor T2 may transmit the data voltage DATA to the first transistor T1. For example, the second transistor T2 may be referred to as a first switching transistor.

The third transistor T3 may include a gate electrode, a first electrode, and a second electrode. The gate electrode of the third transistor T3 may receive the gate signal GS. The third transistor T3 may be turned on or off in response to the gate signal GS. The first electrode of the third transistor T3 may be connected to the first transistor T1. The second electrode of the third transistor T3 may be provided with the initialization voltage VINT. During a period in which the third transistor T3 is turned on, the third transistor T3 may transmit the initialization voltage VINT to the first transistor T1. For example, the third transistor T3 may be referred to as a second switching transistor.

In an embodiment, the gate electrode of the first switching transistor and the gate electrode of the second switching transistor may receive the same signal. In other words, the gate electrode of the second transistor T2 and the gate electrode of the third transistor T3 may receive the same signal. For example, the gate electrode of the second transistor T2 and the gate electrode of the third transistor T3 may receive the same gate signal GS.

In an embodiment, each of the first transistor T1, the second transistor T2, and the third transistor T3 may be an NMOS transistor. Accordingly, an active pattern of each of the first transistor T1, the second transistor T2, and the third transistor T3 may include an oxide semiconductor. The gate signal GS for turning on each of the second transistor T2 and the third transistor T3 may have a high level. However, the disclosure is not limited thereto, and each of the first to third transistors T1, T2, and T3 may be a PMOS transistor.

The storage capacitor CST may include a first electrode and a second electrode. The first electrode of the storage capacitor CST may be connected to the gate electrode of the first transistor T1. The second electrode of the storage capacitor CST may be connected to the first electrode of the third transistor T3. The storage capacitor CST may maintain a voltage level of the gate electrode of the first transistor T1 during an inactive period of the gate signal GS.

The light emitting element LD may include a first electrode and a second electrode. The first electrode of the light emitting element LD may be connected to the second electrode of the first transistor T1. The second electrode of the light emitting element LD may be provided with the common voltage ELVSS. The light emitting element LD may emit light with luminance corresponding to the first driving current. The light emitting element LD may include an organic light emitting element that utilizes an organic material as a light emitting layer, an inorganic light emitting element that utilizes an inorganic material as a light emitting layer, etc.

FIG. 4 is a schematic cross-sectional view illustrating the display device of FIG. 1.

Referring to FIG. 4, the display device DD may include a substrate SUB, a circuit layer CL, the light emitting element LD, a pixel defining layer PDL, and an encapsulation layer TFE. The circuit layer CL may include a lower electrode layer BML, a buffer layer BUF, an active pattern ACT, a gate insulating layer GI, a first conductive layer CL1, a protection layer PVX, and a via-insulating layer VIA). The lower electrode layer BML may include a first lower electrode BE1 and a second lower electrode BE2. The first conductive layer CL1 may include a first electrode E1, a second electrode E2, and a gate electrode GE. The light emitting element LD may include a pixel electrode PE, a light emitting layer EML, and a common electrode CE.

The substrate SUB may include a transparent material or an opaque material. The substrate SUB may be formed of a transparent resin substrate. A polyimide substrate may be an example of the transparent resin substrate. In this case, the polyimide substrate may include a first organic layer, a first barrier layer, a second organic layer, etc. By way of example, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

The lower electrode layer BML may be disposed on the substrate SUB. The lower electrode layer BML may include a metal, an alloy, a metal nitride, a conductive metal oxide, a transparent conductive material, etc. Examples of material that may be used as the lower electrode layer BML may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other.

The lower electrode layer BML may include the first lower electrode BE1 and the second lower electrode BE2. The first lower electrode BE1 and the second lower electrode BE2 may be spaced apart from each other. In an embodiment, different types of electrical signals may be provided to the first lower electrode BE1 and the second lower electrode BE2.

The buffer layer BUF may be disposed on the substrate SUB and the lower electrode layer BML. The buffer layer BUF may prevent diffusion of metal atoms or impurities from the substrate SUB to an upper structure (for example, the active pattern ACT, the first conductive layer CL1, etc.). The buffer layer BUF may serve to improve flatness of a surface of the substrate SUB in case that the surface of the substrate SUB is not uniform. For example, the buffer layer BUF may include an inorganic insulating material. Examples of the inorganic insulating material that may be used as the buffer layer BUF may include silicon oxide (SiOₓ), silicon nitride (SiNₓ), silicon oxynitride (SiOₓN_{y}), etc. These may be used alone or in combination with each other.

The active pattern ACT may be disposed on the buffer layer BUF. The active pattern ACT may include an oxide semiconductor, a silicon semiconductor, an organic semiconductor, etc. In an embodiment, the active pattern ACT may include an oxide semiconductor. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), etc. These may be used alone or in combination with each other. The active pattern ACT may include a first conductor area DI1, a second conductor area DI2, and a channel area CHA positioned between the first conductor area DI1 and the second conductor area DI2. there is. In other words, the first conductor area DI1 and the second conductor area DI2 may be spaced apart from each other with the channel area CHA disposed between the first conductor area DI1 and the second conductor area DI2.

For example, each of the first conductor area DI1 and the second conductor area DI2 may be a doped area doped with an impurity, and the channel area CHA may be a non-doped area or an area doped at a lower concentration compared to the first conductor area DI1 and the second conductor area DI2.

In an embodiment, in the process of etching the first conductive layer CL1 and the gate insulating layer GI during the manufacturing process of the display device DD, a portion of the active pattern ACT which is not covered by the gate insulating layer GI may be removed. Accordingly, an opening OP that penetrates the active pattern ACT in a thickness direction may be defined in a portion of the active pattern ACT. However, even in this case, by bypassing the opening OP, the channel area CHA and the first conductor area DI1 may be electrically connected, and the channel area CHA and the second conductor area DI2 may be electrically connected.

The gate insulating layer GI may be disposed on the buffer layer BUF and the active pattern ACT. The gate insulating layer GI may expose a portion of the active pattern ACT. The gate insulating layer GI may include an inorganic insulating material. Examples of the inorganic insulating material that may be used as the gate insulating layer GI may include silicon oxide (SiOₓ), silicon nitride (SiNₓ), silicon oxynitride (SiOₓN_{y}), etc. These may be used alone or in combination with each other. The gate insulating layer GI may electrically insulate the active pattern ACT and the gate electrode GE.

The first conductive layer CL1 may be disposed on the lower electrode layer BML, the active pattern ACT, and the gate insulating layer GI. The first conductive layer CL1 may include the first electrode E1, the second electrode E2, and the gate electrode GE. The first electrode E1, the second electrode E2, and the gate electrode GE may be spaced apart from each other.

The first electrode E1 may be electrically connected to the first lower electrode BE1. For example, the first electrode E1 may be electrically connected to the first lower electrode BE1 through a contact hole penetrating the buffer layer BUF and the gate insulating layer GI. The first electrode E1 may be electrically connected to the first conductor area DI1. For example, the first electrode E1 may be electrically connected to a portion of the first conductor area DI1 which is not covered by the gate insulating layer GI.

The gate electrode GE may overlap the channel area CHA of the active pattern ACT in a plan view.

The second electrode E2 may be electrically connected to the second lower electrode BE2. For example, the second electrode E2 may be electrically connected to the second lower electrode BE2 through a contact hole penetrating the buffer layer BUF and the gate insulating layer GI. The second electrode E2 may be electrically connected to the second conductor area DI2. For example, the second electrode E2 may be electrically connected to a portion of the second conductor area DI2 which is not covered by the gate insulating layer GI.

The first conductive layer CL1 may include a metal, an alloy, a metal nitride, a conductive metal oxide, a transparent conductive material, etc. These may be used alone or in combination with each other. The first conductive layer CL1 may have a single-layer structure or a multi-layer structure. In an embodiment, the first conductive layer CL1 may include at least one of molybdenum (Mo), aluminum (Al), copper (Cu), and titanium (Ti), and may have a multi-layer structure. For example, the first conductive layer CL1 may have a three-layer structure of Ti/Al/Ti. However, the disclosure is not limited thereto.

In an embodiment, the first electrode E1, the second electrode E2, the gate electrode GE, and the active pattern ACT may define a thin film transistor TFT. For example, the thin film transistor TFT may correspond to the first transistor T1 which is illustrated in FIG. 3. In other words, the thin film transistor TFT may serve as a driving transistor. The gate electrode GE may serve as a gate electrode of the thin film transistor TFT. The first electrode E1 and the second electrode E2 may serve as a source electrode and a drain electrode of the thin film transistor TFT.

The protection layer PVX may be disposed on the buffer layer BUF and the first conductive layer CL1. The protection layer PVX may cover the first electrode E1, the second electrode E2, and the gate electrode GE. The protection layer PVX may cover a portion of the active pattern ACT which is not covered by the gate insulating layer GI. The protection layer PVX may include an inorganic insulating material. Examples of the inorganic insulating material that may be used as the protection layer PVX may include silicon oxide (SiOₓ), silicon nitride (SiNₓ), silicon oxynitride (SiOₓN_{y}), etc. These may be used alone or in combination with each other.

The via-insulating layer VIA may be disposed on the protection layer PVX. The via-insulating layer VIA may include an organic insulating material. Examples of the organic insulating material that may be used as the via-insulating layer VIA may include photoresist, polyacryl-based resin, polyimide-based resin, polyamide-based resin, siloxane-based resin, acryl-based resin, epoxy-based resin, etc. These may be used alone or in combination with each other.

The pixel electrode PE may be disposed on the via-insulating layer VIA. The pixel electrode PE may be electrically connected to the first electrode E1 through a contact hole penetrating the via-insulating layer VIA and the protection layer PVX. Accordingly, the pixel electrode PE may be electrically connected to the thin film transistor TFT. For example, the pixel electrode PE may be a reflective electrode, a semi-transmissive electrode, or a transmissive electrode. The pixel electrode PE may include a metal, an alloy, a metal nitride, a conductive metal oxide, a transparent conductive material, etc. These may be used alone or in combination with each other. For example, the pixel electrode PE may serve as an anode electrode.

In an embodiment, the pixel electrode PE may include a reflective film including at least one of silver (Ag), magnesium (Mg), aluminum (Al), platinum (Pt), palladium (Pd), gold (Au), nickel (Ni), neodymium (Nd), iridium (Ir), and chromium (Cr). The pixel electrode PE may include a conductive metal oxide such as indium tin oxide (ITO), indium zinc oxide (IZO), zinc oxide (ZnO), indium oxide (InOₓ), indium gallium oxide (IGO), aluminum zinc oxide (AZO), etc. These may be used alone or in combination with each other.

The pixel electrode PE may have a single-layer structure or a multi-layer structure. In an embodiment, the pixel electrode PE may include the reflective film and a transparent or translucent electrode disposed on the reflective film. In an embodiment, the pixel electrode PE may include the reflective film and a transparent or translucent electrode disposed under or below the reflective film. For example, the pixel electrode PE may have a three-layer structure of ITO/Ag/ITO. However, the disclosure is not limited thereto.

The pixel defining layer PDL may be disposed on the via-insulating layer VIA. The pixel defining layer PDL may cover an edge of the pixel electrode PE and may expose a portion of an upper surface of the pixel electrode PE. The pixel defining layer PDL may include an organic insulating material and/or an inorganic insulating material. Examples of the organic insulating material that may be used as the pixel defining layer PDL may include photoresist, polyacryl-based resin, polyimide-based resin, polyamide-based resin, siloxane-based resin, acryl-based resin, epoxy-based resin, etc. These may be used alone or in combination with each other.

The light emitting layer EML may be disposed on the pixel electrode PE. The light emitting layer EML may emit light having a given color (for example, red, green and blue). In an embodiment, the light emitting layer EML may include one or both of an organic light emitting material and a quantum dot. For example, the light emitting layer EML may include an organic material including a fluorescent or phosphorescent material that emits red, green, blue, or white light. For example, the light emitting layer EML may have a single-layer structure including one light emitting layer. By way of example, the light emitting layer EML may have a tandem structure.

The common electrode CE may be disposed on the pixel defining layer PDL and the light emitting layer EML. The common electrode CE may cover the pixel defining layer PDL and the light emitting layer EML and may be disposed along the profiles of the pixel defining layer PDL and the light emitting layer EML with a substantially uniform thickness. For example, the common electrode CE may include a metal, an alloy, a metal nitride, a conductive metal oxide, a transparent conductive material, etc. These may be used alone or in combination with each other. For example, the common electrode CE may serve as a cathode electrode.

Accordingly, a light emitting element LD including the pixel electrode PE, the light emitting layer EML, and the common electrode CE may be formed.

The encapsulation layer TFE may be disposed on the common electrode CE. The encapsulation layer TFE may prevent impurities, moisture, etc. from penetrating into the light emitting element LD from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), etc. These may be used alone or in combination with each other. For example, the organic encapsulation layer may include a cured polymer such as polyacrylate.

Although the display device DD of the disclosure is described by limiting the organic light emitting display (OLED) device, the configuration of the disclosure is not limited thereto. In other embodiments, the display device DD may include a liquid crystal display (LCD) device, a field emission display (FED) device, a plasma display panel (PDP) device, an electrophoretic image display (EPD) device, an inorganic light emitting display (ILED) device, or a quantum dot display device.

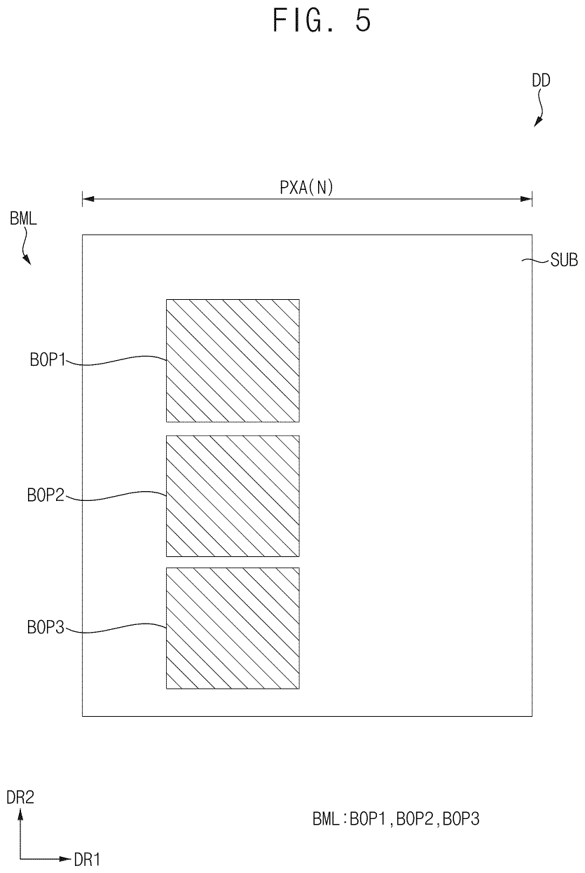

FIGS. 5, 6, 7, and 8 are schematic plan views illustrating a pixel included in the display device of FIGS. 1 and 3. For example, FIGS. 5, 6, 7, and 8 are schematic plan views illustrating the circuit layer CL of FIG. 4. The first to N-th pixel circuits respectively disposed in the first to N-th pixel circuit areas may have substantially the same shape as each other. Therefore, the following description will focus on the N-th pixel circuit disposed in the N-th pixel circuit area PXA (N). At least some of the components illustrated in FIGS. 5 to 8 may be interconnected between the pixel circuits.

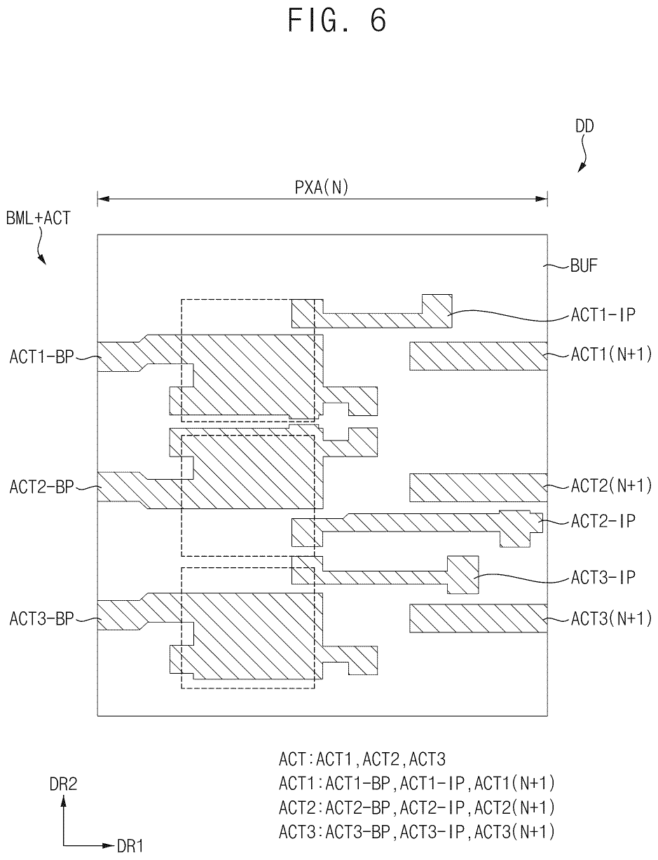

In FIG. 6, a notation BML+ACT means that the lower electrode layer BML and the active pattern ACT disposed on the lower electrode layer BML are illustrated. The active pattern ACT is illustrated by hatching, and components disposed under the active pattern ACT are illustrated by dotted lines.

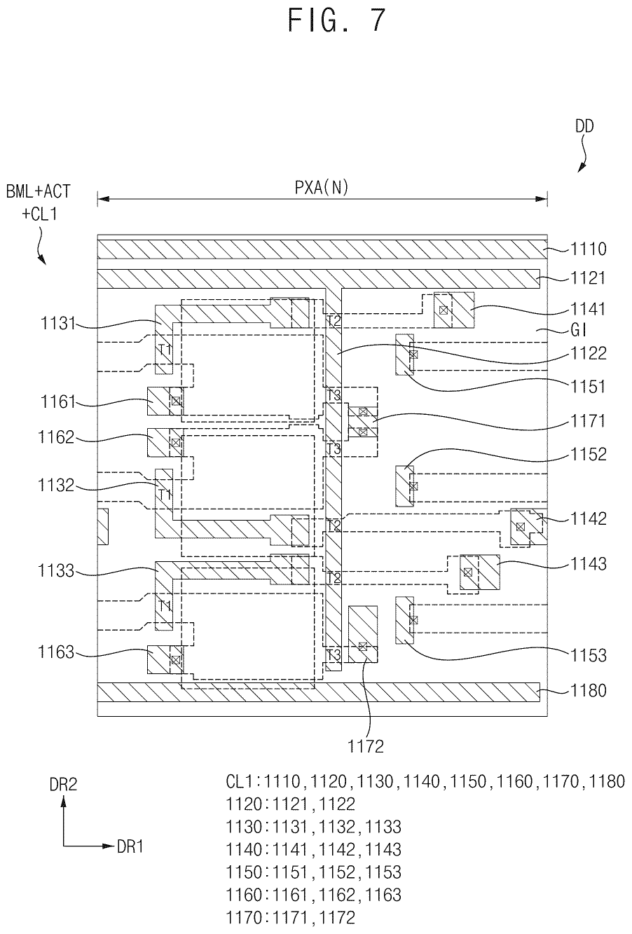

In FIG. 7, a notation BML+ACT+CL1 means that the lower electrode layer BML, the active pattern ACT disposed on the lower electrode layer BML, and the first conductive layer CL1 disposed on the active pattern ACT are illustrated. The first conductive layer CL1 is illustrated by hatching, and components disposed under the first conductive layer CL1 are illustrated by dotted lines.

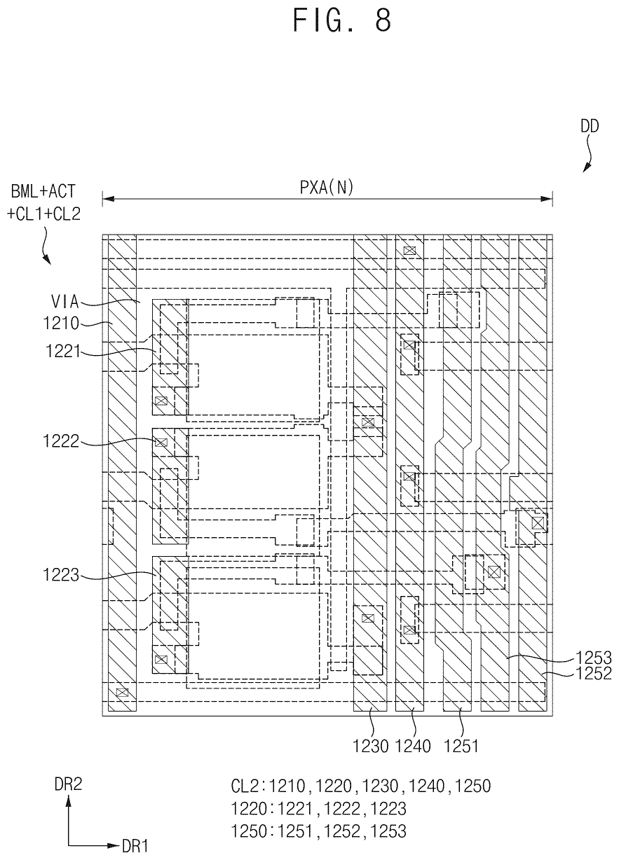

In FIG. 8, a notation BML+ACT+CL1+CL2 means that the lower electrode layer BML, the active pattern ACT disposed on the lower electrode layer BML, the first conductive layer CL1 disposed on the active pattern ACT, and the second conductive layer CL2 disposed on the first conductive layer CL1 are illustrated. The second conductive layer CL2 is illustrated by hatching, and components disposed under the second conductive layer CL2 are illustrated by dotted lines.

Referring to FIGS. 1, 3, and 5, the lower electrode layer BML may be disposed on the substrate SUB. The lower electrode layer BML may include a first lower pattern BOP1, a second lower pattern BOP2, and a third lower pattern BOP3. The first lower pattern BOP1, the second lower pattern BOP2, and the third lower pattern BOP3 may be spaced apart from each other. Each of the first lower pattern BOP1, the second lower pattern BOP2, and the third lower pattern BOP3 may correspond to the second lower electrode BE2 of FIG. 4.

Referring further to FIG. 6, the buffer layer BUF may be disposed on the lower electrode layer BML.

The buffer layer BUF may include an inorganic insulating material. Examples of the inorganic insulating material that may be used as the buffer layer BUF may include silicon oxide (SiOₓ), silicon nitride (SiNₓ), silicon oxynitride (SiOₓN_{y}), etc. These may be used alone or in combination with each other.

The active pattern ACT may be disposed on the buffer layer BUF. The active pattern ACT may include a first active pattern ACT1, a second active pattern ACT2, and a third active pattern ACT3. Hereinafter, the description will focus on the first active pattern ACT1.

The first active pattern ACT1 may be an active pattern for driving the light emitting element LD included in the first sub-pixel SPX1. The first active pattern ACT1 may include a first body portion ACT1-BP, a first independent portion ACT1-IP, and a first body portion ACT1(N+1) of an (N+1)-th pixel circuit. The first independent portion ACT1-IP may be spaced apart from the first body portion ACT1-BP. Although not illustrated in FIG. 6, a portion having substantially the same shape as the first body portion ACT1(N+1) of the (N+1)-th pixel circuit may be adjacent to the first body portion ACT1-BP in the first direction DR1. Similarly, a portion having substantially the same shape as the first body portion ACT1-BP may be adjacent to the first body portion ACT1(N+1) of the (N+1)-th pixel circuit in the first direction DR1.

The second active pattern ACT2 may be an active pattern for driving the light emitting element LD included in the second sub-pixel SPX2. The second active pattern ACT2 may include a second body portion ACT2-BP, a second independent portion ACT2-IP, and a second body portion ACT2(N+1) of the (N+1)-th pixel circuit.

The third active pattern ACT3 may be an active pattern for driving the light emitting element LD included in the third sub-pixel SPX3. The third active pattern ACT3 may include a third body portion ACT3-BP, a third independent portion ACT3-IP, and a third body portion ACT3(N+1) of the (N+1)-th pixel circuit.

In an embodiment, each of the first to third active patterns ACT1, ACT2, and ACT3 may include an oxide semiconductor.

Referring further to FIG. 7, the gate insulating layer GI may be disposed on the active pattern ACT and may cover the active pattern ACT.

The gate insulating layer GI may include an inorganic insulating material. Examples of the inorganic insulating material that may be used as the gate insulating layer GI may include silicon oxide (SiOₓ), silicon nitride (SiNₓ), silicon oxynitride (SiOₓN_{y}), etc. These may be used alone or in combination with each other.

The first conductive layer CL1 may be disposed on the gate insulating layer GI. The first conductive layer CL1 may include first to eighth gate patterns 1110, 1120, 1130, 1140, 1150, 1160, 1170, and 1180. The first to eighth gate patterns 1110, 1120, 1130, 1140, 1150, 1160, 1170, and 1180 may be disposed in the same layer and may include the same material. The first conductive layer CL1 may include a metal, an alloy, a metal nitride, a conductive metal oxide, a transparent conductive material, etc. These may be used alone or in combination with each other.

The first conductive layer CL1 may at least partially overlap the active pattern ACT. An overlapping portion between the first conductive layer CL1 and the active pattern ACT may define a portion of a transistor.

The first gate pattern 1110 may extend in the first direction DR1. The driving voltage ELVDD may be provided to the first gate pattern 1110.

The second gate pattern 1120 may be spaced apart from the first gate pattern 1110. The second gate pattern 1120 may include a first portion 1121 extending in the first direction DR1 and a second portion 1122 extending in the second direction DR2. The gate signal GS may be provided to the second gate pattern 1120. For example, the second gate pattern 1120 may correspond to the gate line GL of FIG. 2.

The second portion 1122 of the second gate pattern 1120 may overlap each of the first independent portion ACT1-IP, the second independent portion ACT2-IP, and the third independent portion ACT3-IP. A portion of the second portion 1122 of the second gate pattern 1120 overlapping the first independent portion ACT1-IP may correspond to the gate electrode of the second transistor T2 of the first sub-pixel circuit. A portion of the second portion 1122 of the second gate pattern 1120 overlapping the second independent portion ACT2-IP may correspond to the gate electrode of the second transistor T2 of the second sub-pixel circuit. A portion of the second portion 1122 of the second gate pattern 1120 overlapping the third independent portion ACT3-IP may correspond to the gate electrode of the second transistor T2 of the third sub-pixel circuit.

The second portion 1122 of the second gate pattern 1120 may overlap each of the first body portion ACT1-BP, the second body portion ACT2-BP, and the third body portion ACT3-BP. A portion of the second portion 1122 of the second gate pattern 1120 overlapping the first body portion ACT1-BP may correspond to the gate electrode of the third transistor T3 of the first sub-pixel circuit. A portion of the second portion 1122 of the second gate pattern 1120 overlapping the second body portion ACT2-BP may correspond to the gate electrode of the third transistor T3 of the second sub-pixel circuit. A portion of the second portion 1122 of the second gate pattern 1120 overlapping the third body portion ACT3-BP may correspond to the gate electrode of the third transistor T3 of the third sub-pixel circuit.

The third gate pattern 1130 may be spaced apart from the second gate pattern 1120. The third gate pattern 1130 may include a (3-1)-th gate pattern 1131, a (3-2)-th gate pattern 1132, and a (3-3)-th gate pattern 1133.

The (3-1)-th gate pattern 1131 may overlap the first body portion ACT1-BP. A portion of the (3-1)-th gate pattern 1131 overlapping the first body portion ACT1-BP may correspond to the gate electrode of the first transistor T1 of the first sub-pixel circuit.

The (3-1)-th gate pattern 1131 may overlap the first lower pattern BOP1. In an area where the first lower pattern BOP1 and the (3-1)-th gate pattern 1131 overlap, the first lower pattern BOP1 and the (3-1)-th gate pattern 1131 may form the storage capacitor CST of the first sub-pixel circuit.

The (3-2)-th gate pattern 1132 may overlap the second body portion ACT2-BP. A portion of the (3-2)-th gate pattern 1132 overlapping the second body portion ACT2-BP may correspond to the gate electrode of the first transistor T1 of the second sub-pixel circuit.

The (3-2)-th gate pattern 1132 may overlap the second lower pattern BOP2. In an area where the second lower pattern BOP2 and the (3-2)-th gate pattern 1132 overlap, the second lower pattern BOP2 and the (3-2)-th gate pattern 1132 may form the storage capacitor CST of the second sub-pixel circuit.

The (3-3)-th gate pattern 1133 may overlap the third body portion ACT3-BP. A portion of the (3-3)-th gate pattern 1133 overlapping the third body portion ACT3-BP may correspond to the gate electrode of the first transistor T1 of the third sub-pixel circuit.

The (3-3)-th gate pattern 1133 may overlap the third lower pattern BOP3. In an area where the third lower pattern BOP3 and the (3-3)-th gate pattern 1133 overlap, the third lower pattern BOP3 and the (3-3)-th gate pattern 1133 may form the storage capacitor CST of the third sub-pixel circuit.

The fourth gate pattern 1140 may be spaced apart from the third gate pattern 1130. The data voltage DATA may be provided to the fourth gate pattern 1140. For example, the fourth gate pattern 1140 may be referred to as a data connection electrode. The fourth gate pattern 1140 may include a (4-1)-th gate pattern 1141, a (4-2)-th gate pattern 1142, and a (4-3)-th gate pattern 1143. The data voltage DATA may include a red data voltage, a green data voltage, and a blue data voltage.

The red data voltage may be provided to the (4-1)-th gate pattern 1141. The (4-1)-th gate pattern 1141 may be connected to the first independent portion ACT1-IP through a contact hole. Accordingly, the red data voltage may be provided to the second transistor T2 of the first sub-pixel circuit.

The green data voltage may be provided to the (4-2)-th gate pattern 1142. The (4-2)-th gate pattern 1142 may be connected to the second independent portion ACT2-IP through a contact hole. Accordingly, the green data voltage may be provided to the second transistor T2 of the second sub-pixel circuit.

The blue data voltage may be provided to the (4-3)-th gate pattern 1143. The (4-3)-th gate pattern 1143 may be connected to the third independent portion ACT3-IP through a contact hole. Accordingly, the blue data voltage may be provided to the second transistor T2 of the third sub-pixel circuit.

The fifth gate pattern 1150 may be spaced apart from the fourth gate pattern 1140. The driving voltage ELVDD may be provided to the fifth gate pattern 1150. For example, the fifth gate pattern 1150 may be referred to as a driving voltage connection electrode. The fifth gate pattern 1150 may include a (5-1)-th gate pattern 1151, a (5-2)-th gate pattern 1152, and a (5-3)-th gate pattern 1153.

The (5-1)-th gate pattern 1151 may be connected to the first body portion ACT1(N+1) of the (N+1)-th pixel circuit through a contact hole. Accordingly, the (5-1)-th gate pattern 1151 may provide the driving voltage ELVDD to the first transistor T1 of the first sub-pixel circuit included in the (N+1)-th pixel circuit.

The (5-2)-th gate pattern 1152 may be connected to the second body portion ACT2(N+1) of the (N+1)-th pixel circuit through a contact hole. Accordingly, the (5-2)-th gate pattern 1152 may provide the driving voltage ELVDD to the first transistor T1 of the second sub-pixel circuit included in the (N+1)-th pixel circuit.

The (5-3)-th gate pattern 1153 may be connected to the third body portion ACT3(N+1) of the (N+1)-th pixel circuit through a contact hole. Accordingly, the (5-3)-th gate pattern 1153 may provide the driving voltage ELVDD to the first transistor T1 of the third sub-pixel circuit included in the (N+1)-th pixel circuit.

The sixth gate pattern 1160 may be spaced apart from the fifth gate pattern 1150. The sixth gate pattern 1160 may provide a driving current to the light emitting element LD. For example, the sixth gate pattern 1160 may be referred to as a lower light emitting element connection electrode. The sixth gate pattern 1160 may include a (6-1)-th gate pattern 1161, a (6-2)-th gate pattern 1162, and a (6-3)-th gate pattern 1163.

The (6-1)-th gate pattern 1161 may be connected to the first body portion ACT1-BP through a contact hole. Accordingly, the (6-1)-th gate pattern 1161 may provide the first driving current to the light emitting element LD included in the first sub-pixel SPX1.

The (6-2)-th gate pattern 1162 may be connected to the second body portion ACT2-BP through a contact hole. Accordingly, the (6-2)-th gate pattern 1162 may provide the second driving current to the light emitting element LD included in the second sub-pixel SPX2.

The (6-3)-th gate pattern 1163 may be connected to the third body portion ACT3-BP through a contact hole. Accordingly, the (6-3)-th gate pattern 1163 may provide the third driving current to the light emitting element LD included in the third sub-pixel SPX3.

The seventh gate pattern 1170 may be spaced apart from the sixth gate pattern 1160. The initialization voltage VINT may be provided to the seventh gate pattern 1170. For example, the seventh gate pattern 1170 may be referred to as an initialization voltage connection electrode. The seventh gate pattern 1170 may include a (7-1)-th gate pattern 1171 and a (7-2)-th gate pattern 1172.

The (7-1)-th gate pattern 1171 may be connected to the first body portion ACT1-BP through a contact hole. Accordingly, the initialization voltage VINT may be provided to the third transistor T3 of the first sub-pixel circuit. The (7-1)-th gate pattern 1171 may be connected to the second body portion ACT2-BP through a contact hole. Accordingly, the initialization voltage VINT may be provided to the third transistor T3 of the second sub-pixel circuit.

The (7-2)-th gate pattern 1172 may be connected to the third body portion ACT3-BP through a contact hole. Accordingly, the initialization voltage VINT may be provided to the third transistor T3 of the third sub-pixel circuit.

The eighth gate pattern 1180 may extend in the first direction DR1 and may be spaced apart from the seventh gate pattern 1170. The common voltage ELVSS may be provided to the eighth gate pattern 1180.

Referring further to FIG. 8, the protection layer (for example, the protection layer PVX of FIG. 4) may be disposed on the first conductive layer CL1, and the via-insulating layer VIA may be disposed on the protection layer.

The protection layer may include an inorganic insulating material. Examples of the inorganic insulating material that may be used as the protection layer may include silicon oxide (SiOₓ), silicon nitride (SiNₓ), silicon oxynitride (SiOₓN_{y}), etc. These may be used alone or in combination with each other. The via-insulating layer VIA may include an organic insulating material. Examples of the organic insulating material that may be used as the via-insulating layer VIA may include photoresist, polyacryl-based resin, polyimide-based resin, polyamide-based resin, siloxane-based resin, acryl-based resin, epoxy-based resin, etc. These may be used alone or in combination with each other.

A second conductive layer CL2 may be disposed on the via-insulating layer VIA. The second conductive layer CL2 may include the common voltage line 1210, a light emitting element connection electrode 1220, the initialization voltage line 1230, the driving voltage line 1240, and the data lines 1250. The common voltage line 1210, the light emitting element connection electrode 1220, the initialization voltage line 1230, the driving voltage line 1240, and the data lines 1250 may be disposed in the same layer and may include the same material. The second conductive layer CL2 may include a metal, an alloy, a metal nitride, a conductive metal oxide, a transparent conductive material, etc. These may be used alone or in combination with each other.

The common voltage line 1210 may extend in the second direction DR2. The common voltage line 1210 may be connected to the eighth gate pattern 1180 through a contact hole. Accordingly, the common voltage ELVSS may be provided to the common voltage line 1210.

The light emitting element connection electrode 1220 may provide the driving current to the light emitting element LD. For example, the light emitting element connection electrode 1220 may be referred to as an upper light emitting element connection electrode. The light emitting element connection electrode 1220 may include a first light emitting element connection electrode 1221, a second light emitting element connection electrode 1222, and a third light emitting element connection electrode 1223.

The first light emitting element connection electrode 1221 may be connected to the (6-1)-th gate pattern 1161 through a contact hole. Accordingly, the first light emitting element connection electrode 1221 may provide the first driving current to the light emitting element LD included in the first sub-pixel SPX1.

The second light emitting element connection electrode 1222 may be connected to the (6-2)-th gate pattern 1162 through a contact hole. Accordingly, the second light emitting element connection electrode 1222 may provide the second driving current to the light emitting element LD included in the second sub-pixel SPX2.

The third light emitting element connection electrode 1223 may be connected to the (6-3)-th gate pattern 1163 through a contact hole. Accordingly, the third light emitting element connection electrode 1223 may provide the third driving current to the light emitting element LD included in the third sub-pixel SPX3.

The initialization voltage line 1230 may extend in the second direction DR2 and may be spaced apart from the light emitting element connection electrode 1220. The initialization voltage VINT may be provided to the initialization voltage line 1230. The initialization voltage line 1230 may be connected to the (7-1)-th gate pattern 1171 and the (7-2)-th gate pattern 1172 through a contact hole. Accordingly, the initialization voltage VINT may be provided to the (7-1)-th gate pattern 1171 and the (7-2)-th gate pattern 1172.

The driving voltage line 1240 may extend in the second direction DR2 and may be adjacent to the initialization voltage line 1230 in the first direction DR1. The driving voltage line 1240 may be connected to the first gate pattern 1110 through a contact hole. Accordingly, the driving voltage ELVDD may be provided to the driving voltage line 1240.

In an embodiment, the driving voltage line 1240 overlapping the N-th pixel circuit area PXA(N) may provide the driving voltage ELVDD to the first transistor T1 included in the (N+1)-th pixel circuit.

The driving voltage line 1240 may be connected to the (5-1)-th gate pattern 1151 through a contact hole. Accordingly, the driving voltage line 1240 may provide the driving voltage ELVDD to the (5-1)-th gate pattern 1151. For example, the driving voltage line 1240 may provide the driving voltage ELVDD to the first transistor T1 of the first sub-pixel circuit included in the (N+1)-th pixel circuit through the (5-1)-th gate pattern 1151.

The driving voltage line 1240 may be connected to the (5-2)-th gate pattern 1152 through a contact hole. Accordingly, the driving voltage line 1240 may provide the driving voltage ELVDD to the (5-2)-th gate pattern 1152. For example, the driving voltage line 1240 may provide the driving voltage ELVDD to the first transistor T1 of the second sub-pixel circuit included in the (N+1)-th pixel circuit through the (5-2)-th gate pattern 1152.

The driving voltage line 1240 may be connected to the (5-3)-th gate pattern 1153 through a contact hole. Accordingly, the driving voltage line 1240 may provide the driving voltage ELVDD to the (5-3)-th gate pattern 1153. For example, the driving voltage line 1240 may provide the driving voltage ELVDD to the first transistor T1 of the third sub-pixel circuit included in the (N+1)-th pixel circuit through the (5-3)-th gate pattern 1153.

Each of the data lines 1250 may extend in the second direction DR2. The data lines 1250 may be spaced apart from the initialization voltage line 1230 in the first direction DR1 with the driving voltage line 1240 disposed between the data lines 1250 and the initialization voltage line 1230. The data lines 1250 may include a first data line 1251, a second data line 1252, and a third data line 1253.

The red data voltage may be provided to the first data line 1251. The first data line 1251 may be connected to the (4-1)-th gate pattern 1141 through a contact hole. Accordingly, the red data voltage may be provided to the (4-1)-th gate pattern 1141.

The green data voltage may be provided to the second data line 1252. The second data line 1252 may be connected to the (4-2)-th gate pattern 1142 through a contact hole. Accordingly, the green data voltage may be provided to the (4-2)-th gate pattern 1142.

The blue data voltage may be provided to the third data line 1253. The third data line 1253 may be connected to the (4-3)-th gate pattern 1143 through a contact hole. Accordingly, the blue data voltage may be provided to the (4-3)-th gate pattern 1143.

In an embodiment, the common voltage line 1210, the driving voltage line 1240, and the data lines 1250 may be disposed in an order of the driving voltage line 1240, the data lines 1250, and the common voltage line 1210 in the first direction DR1. Although not illustrated in FIG. 8, the common voltage line 1210 overlapping the (N+1)-th pixel circuit area PXA(N+1) may be adjacent to the data lines 1250 overlapping the N-th pixel circuit area PXA(N) in the first direction DR1. For example, the common voltage line 1210, the driving voltage line 1240, and the data lines 1250 may be disposed in the first direction DR1 in an order of the driving voltage line 1240, the first data line 1251, the third data line 1253, the second data line 1252, and the common voltage line 1210 overlapping the (N+1)-th pixel circuit area PXA(N+1).

In a conventional display device, in case that the initialization voltage line 1230 and the data lines 1250 are disposed adjacent to each other, a parasitic capacitance (for example, coupling capacitance) may form between the initialization voltage line 1230 and the data lines 1250. Due to the parasitic capacitance, horizontal crosstalk may occur, resulting in deteriorated display quality.

The display device DD according to an embodiment may include the initialization voltage line 1230, the driving voltage line 1240 adjacent to the initialization voltage line 1230 in the first direction DR1, and the data lines 1250 spaced apart from the initialization voltage line 1230 in the first direction DR1 with the driving voltage line 1240 disposed between the data lines 1250 and the initialization voltage line 1230. As the data lines 1250 are spaced apart from the initialization voltage line 1230 in the first direction DR1 with the driving voltage line 1240 disposed between the data lines 1250 and the initialization voltage line 1230, the formation of the parasitic capacitance between the initialization voltage line 1230 and the data lines 1250 may be reduced. For example, the driving voltage line 1240 may be disposed between the initialization voltage line 1230 and the data lines 1250 to suppress the formation of the parasitic capacitance. Accordingly, the occurrence of horizontal crosstalk in the display device DD may be reduced, and the display quality of the display device DD may be improved.

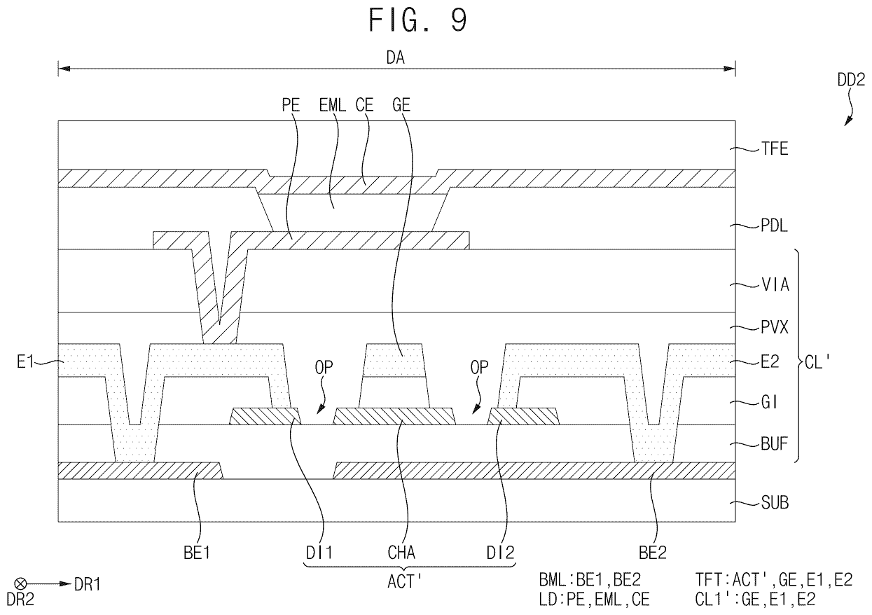

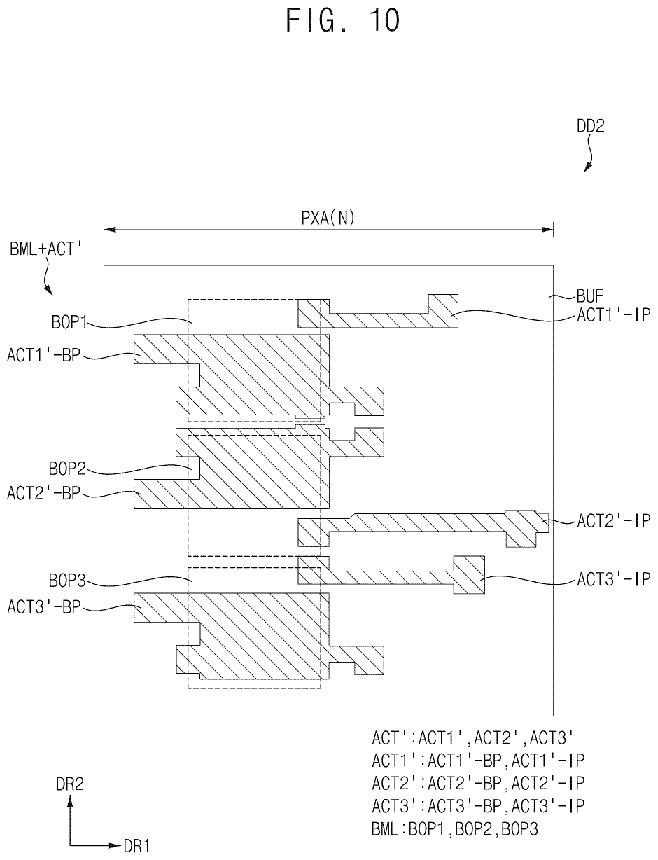

FIG. 9 is a schematic cross-sectional view illustrating a display device according to an embodiment. FIGS. 10, 11, and 12 are schematic plan views illustrating a pixel included in the display device of FIG. 9. For example, FIGS. 10, 11, and 12 are schematic plan views illustrating a circuit layer CL′ of FIG. 9. The first to N-th pixel circuits respectively disposed in the first to N-th pixel circuit areas may have substantially the same shape as each other. Therefore, the following description will focus on the N-th pixel circuit disposed in the N-th pixel circuit area PXA(N). At least some of the components illustrated in FIGS. 10 to 12 may be interconnected between the pixel circuits.

In FIG. 10, a notation BML+ACT′ means that the lower electrode layer BML and an active pattern ACT′ disposed on the lower electrode layer BML are illustrated. The active pattern ACT′ is illustrated by hatching, and components disposed under the active pattern ACT′ are illustrated by dotted lines.

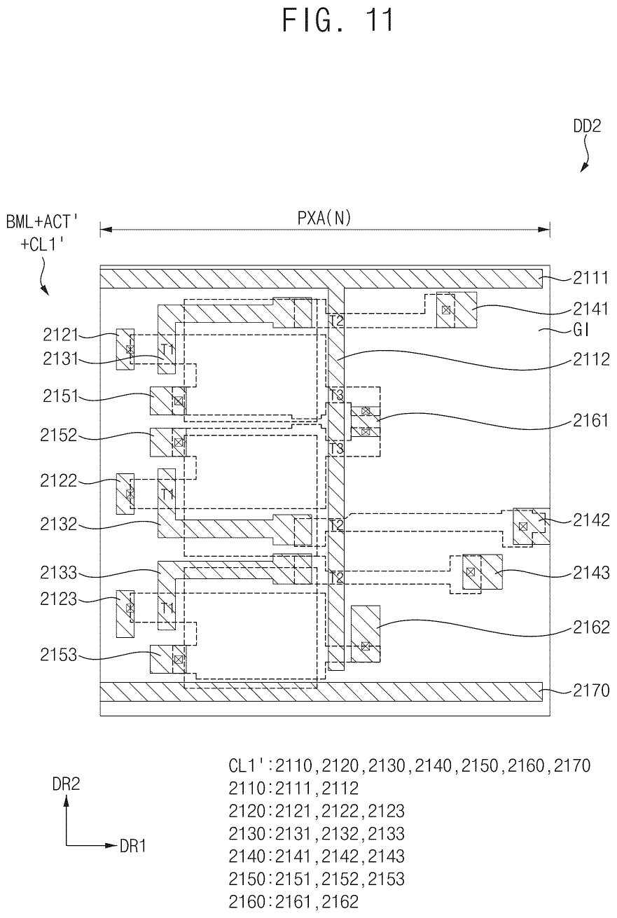

In FIG. 11, a notation BML+ACT′+CL1′ means that the lower electrode layer BML, the active pattern ACT′ disposed on the lower electrode layer BML, and a first conductive layer CL1′ disposed on the active pattern ACT′ are illustrated. The first conductive layer CL1′ is illustrated by hatching, and components disposed under the first conductive layer CL1′ are illustrated by dotted lines.

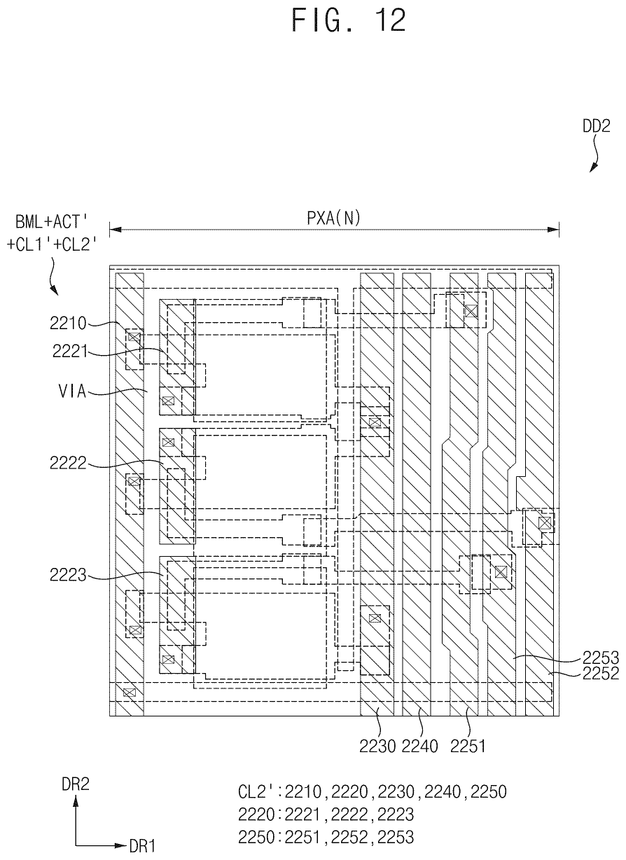

In FIG. 12, a notation BML+ACT′+CL1′+CL2′ means that the lower electrode layer BML, the active pattern ACT′ disposed on the lower electrode layer BML, the first conductive layer CL1′ disposed on the active pattern ACT′, and a second conductive layer CL2′ disposed on the first conductive layer CL1′ are illustrated. The second conductive layer CL2′ is illustrated by hatching, and components disposed under the second conductive layer CL2′ are illustrated by dotted lines.

Referring to FIG. 9, a display device DD2 according to an embodiment may include the substrate SUB, a circuit layer CL′, the light emitting element LD, the pixel defining layer PDL, and the encapsulation layer TFE. The circuit layer CL′ may include the lower electrode layer BML, the buffer layer BUF, an active pattern ACT′, the gate insulating layer GI, a first conductive layer CL1′, the protection layer PVX, and the via-insulating layer VIA. The lower electrode layer BML may include the first lower electrode BE1 and the second lower electrode BE2. The first conductive layer CL1′ may include the first electrode E1, the second electrode E2, and the gate electrode GE. The light emitting element LD may include the pixel electrode PE, the light emitting layer EML, and the common electrode CE.

The display device DD2 may be substantially the same as the display device DD described with reference to FIGS. 1 to 8 except for the shape in which the circuit layer CL′ is disposed in a plan view. For example, the display device DD2 may be substantially the same as the display device DD described with reference to FIGS. 1 to 8, except for position where a driving voltage line (for example, a driving voltage line 2210 of FIG. 12) and a common voltage line (for example, a common voltage line 2240 of FIG. 12) are disposed in a plan view. Hereinafter, descriptions overlapping descriptions of the display device DD described with reference to FIGS. 1 to 8 will be omitted or simplified.

Referring to FIGS. 1, 3, and 10, the lower electrode layer BML may be disposed on the substrate SUB, the buffer layer BUF may be disposed on the lower electrode layer BML, and the active pattern ACT′ may be disposed on the buffer layer BUF.

The lower electrode layer BML may include the first lower pattern BOP1, the second lower pattern BOP2, and the third lower pattern BOP3. The first lower pattern BOP1, the second lower pattern BOP2, and the third lower pattern BOP3 may be spaced apart from each other. Each of the first lower pattern BOP1, the second lower pattern BOP2, and the third lower pattern BOP3 may correspond to the second lower electrode BE2 of FIG. 9.

The active pattern (ACT′) may include a first active pattern (ACT1′), a second active pattern (ACT2′), and a third active pattern (ACT3′).

The first active pattern ACT1′ may be an active pattern for driving the light emitting element LD included in the first sub-pixel SPX1. The first active pattern ACT1′ may include a first body portion ACT1′-BP and a first independent portion ACT1′-IP.

The second active pattern ACT2′ may be an active pattern for driving the light emitting element LD included in the second sub-pixel SPX2. The second active pattern ACT2′ may include a second body portion ACT2′-BP and a second independent portion ACT2′-IP.

The third active pattern ACT3′ may be an active pattern for driving the light emitting element LD included in the third sub-pixel SPX3. The third active pattern ACT3′ may include a third body portion ACT3′-BP and a third independent portion ACT3′-IP.

Referring further to FIG. 11, the gate insulating layer GI may be disposed on the active pattern ACT′ and may cover the active pattern ACT′. The first conductive layer CL1′ may be disposed on the gate insulating layer GI.

The first conductive layer CL1′ may include first to seventh gate patterns 2110, 2120, 2130, 2140, 2150, 2160, and 2170. The first to seventh gate patterns 2110, 2120, 2130, 2140, 2150, 2160, and 2170 may be disposed in the same layer and may include the same material.

The first conductive layer CL1′ may at least partially overlap the active pattern ACT′. An overlapping portion of the first conductive layer CL1′ and the active pattern ACT′ may define a portion of a transistor.

The first gate pattern 2110 may include a first portion 2111 extending in the first direction DR1 and a second portion 2112 extending in the second direction DR2. The gate signal GS may be provided to the first gate pattern 2110. For example, the first gate pattern 2110 may correspond to the gate line GL of FIG. 2.

The second portion 2112 of the first gate pattern 2110 may overlap each of the first independent portion ACT1′-IP, the second independent portion ACT2′-IP, and the third independent portion ACT3′-IP. A portion of the second portion 2112 of the first gate pattern 2110 overlapping the first independent portion ACT1′-IP may correspond to the gate electrode of the second transistor T2 of the first sub-pixel circuit. A portion of the second portion 2112 of the first gate pattern 2110 overlapping the second independent portion ACT2′-IP may correspond to the gate electrode of the second transistor T2 of the second sub-pixel circuit. A portion of the second portion 2112 of the first gate pattern 2110 overlapping the third independent portion ACT3′-IP may correspond to the gate electrode of the second transistor T2 of the third sub-pixel circuit.

The second portion 2112 of the first gate pattern 2110 may overlap each of the first body portion ACT1′-BP, the second body portion ACT2′-BP, and the third body portion ACT3′-BP. A portion of the second portion 2112 of the first gate pattern 2110 overlapping the first body portion ACT1′-BP may correspond to the gate electrode of the third transistor T3 of the first sub-pixel circuit. A portion of the second portion 2112 of the first gate pattern 2110 overlapping the second body portion ACT2′-BP may correspond to the gate electrode of the third transistor T3 of the second sub-pixel circuit. A portion of the second portion 2112 of the first gate pattern 2110 overlapping the third body portion ACT3′-BP may correspond to the gate electrode of the third transistor T3 of the third sub-pixel circuit.

The second gate pattern 2120 may be spaced apart from the first gate pattern 2110. The driving voltage ELVDD may be provided to the second gate pattern 2120. For example, the second gate pattern 2120 may be referred to as a driving voltage connection electrode. The second gate pattern 2120 may include a (2-1)-th gate pattern 2121, a (2-2)-th gate pattern 2122, and a (2-3)-th gate pattern 2123.

The (2-1)-th gate pattern 2121 may be connected to the first body portion ACT1′-BP through a contact hole. Accordingly, the (2-1)-th gate pattern 2121 may provide the driving voltage ELVDD to the first transistor T1 of the first sub-pixel circuit. In other words, the (2-1)-th gate pattern 2121 may provide the driving voltage ELVDD to the first transistor T1 of the first sub-pixel circuit included in the N-th pixel circuit.

The (2-2)-th gate pattern 2122 may be connected to the second body portion ACT2′-BP through a contact hole. Accordingly, the (2-2)-th gate pattern 2122 may provide the driving voltage ELVDD to the first transistor T1 of the second sub-pixel circuit. In other words, the (2-2)-th gate pattern 2122 may provide the driving voltage ELVDD to the first transistor T1 of the second sub-pixel circuit included in the N-th pixel circuit.

The (2-3)-th gate pattern 2123 may be connected to the third body portion ACT3′-BP through a contact hole. Accordingly, the (2-3)-th gate pattern 2123 may provide the driving voltage ELVDD to the first transistor T1 of the third sub-pixel circuit. In other words, the (2-3)-th gate pattern 2123 may provide the driving voltage ELVDD to the first transistor T1 of the third sub-pixel circuit included in the N-th pixel circuit.

The third gate pattern 2130 may be spaced apart from the second gate pattern 2120. The third gate pattern 2130 may include a (3-1)-th gate pattern 2131, a (3-2)-th gate pattern 2132, and a (3-3)-th gate pattern 2133.

The (3-1)-th gate pattern 2131 may overlap the first body portion ACT1′-BP. A portion of the (3-1)-th gate pattern 2131 overlapping the first body portion ACT1′-BP may correspond to the gate electrode of the first transistor T1 of the first sub-pixel circuit. The (3-1)-th gate pattern 2131 may overlap the first lower pattern BOP1. In an area where the first lower pattern BOP1 and the (3-1)-th gate pattern 2131 overlap, the first lower pattern BOP1 and the (3-1)-th gate pattern 2131 may form the storage capacitor CST of the first sub-pixel circuit.

The (3-2)-th gate pattern 2132 may overlap the second body portion ACT2′-BP. A portion of the (3-2)-th gate pattern 2132 overlapping the second body portion ACT2′-BP may correspond to the gate electrode of the first transistor T1 of the second sub-pixel circuit. The (3-2)-th gate pattern 2132 may overlap the second lower pattern BOP2. In an area where the second lower pattern BOP2 and the (3-2)-th gate pattern 2132 overlap, the second lower pattern BOP2 and the (3-2)-th gate pattern 2132 may form the storage capacitor CST of the second sub-pixel circuit.

The (3-3)-th gate pattern 2133 may overlap the third body portion ACT3′-BP. A portion of the (3-3)-th gate pattern 2133 overlapping the third body portion ACT3′-BP may correspond to the gate electrode of the first transistor T1 of the third sub-pixel circuit. The (3-3)-th gate pattern 2133 may overlap the third lower pattern BOP3. In an area where the third lower pattern BOP3 and the (3-3)-th gate pattern 2133 overlap, the third lower pattern BOP3 and the (3-3)-th gate pattern 2133 may form the storage capacitor CST of the third sub-pixel circuit.

The fourth gate pattern 2140 may be spaced apart from the third gate pattern 2130. The data voltage DATA may be provided to the fourth gate pattern 2140. For example, the fourth gate pattern 2140 may be referred to as a data connection electrode. The fourth gate pattern 2140 may include a (4-1)-th gate pattern 2141, a (4-2)-th gate pattern 2142, and a (4-3)-th gate pattern 2143. The data voltage DATA may include a red data voltage, a green data voltage, and a blue data voltage.

The red data voltage may be provided to the (4-1)-th gate pattern 2141. The (4-1)-th gate pattern 2141 may be connected to the first independent portion ACT1′-IP through a contact hole. Accordingly, the red data voltage may be provided to the second transistor T2 of the first sub-pixel circuit.

The green data voltage may be provided to the (4-2)-th gate pattern 2142. The (4-2)-th gate pattern 2142 may be connected to the second independent portion ACT2′-IP through a contact hole. Accordingly, the green data voltage may be provided to the second transistor T2 of the second sub-pixel circuit.

The blue data voltage may be provided to the (4-3)-th gate pattern 2143. The (4-3)-th gate pattern 2143 may be connected to the third independent portion ACT3′-IP through a contact hole. Accordingly, the blue data voltage may be provided to the second transistor T2 of the third sub-pixel circuit.

The fifth gate pattern 2150 may be spaced apart from the fourth gate pattern 2140. The fifth gate pattern 2150 may provide a driving current to the light emitting element LD. For example, the fifth gate pattern 2150 may be referred to as a lower light emitting element connection electrode. The fifth gate pattern 2150 may include a (5-1)-th gate pattern 2151, a (5-2)-th gate pattern 2152, and a (5-3)-th gate pattern 2153.

The (5-1)-th gate pattern 2151 may be connected to the first body portion ACT1′-BP through a contact hole. Accordingly, the (5-1)-th gate pattern 2151 may provide a first driving current to the light emitting element LD included in the first sub-pixel SPX1.

The (5-2)-th gate pattern 2152 may be connected to the second body portion ACT2′-BP through a contact hole. Accordingly, the (5-2)-th gate pattern 2152 may provide a second driving current to the light emitting element LD included in the second sub-pixel SPX2.

The (5-3)-th gate pattern 2153 may be connected to the third body portion ACT3′-BP through a contact hole. Accordingly, the (5-3)-th gate pattern 2153 may provide a third driving current to the light emitting element LD included in the third sub-pixel SPX3.

The sixth gate pattern 2160 may be spaced apart from the fifth gate pattern 2150. The initialization voltage VINT may be provided to the sixth gate pattern 2160. For example, the sixth gate pattern 2160 may be referred to as an initialization voltage connection electrode. The sixth gate pattern 2160 may include a (6-1)-th gate pattern 2161 and a (6-2)-th gate pattern 2162.

The (6-1)-th gate pattern 2161 may be connected to the first body portion ACT1′-BP through a contact hole. Accordingly, the initialization voltage VINT may be provided to the third transistor T3 of the first sub-pixel circuit. The (6-1)-th gate pattern 2161 may be connected to the second body portion ACT2′-BP through a contact hole. Accordingly, the initialization voltage VINT may be provided to the third transistor T3 of the second sub-pixel circuit.

The (6-2)-th gate pattern 2162 may be connected to the third body portion ACT3′-BP

through a contact hole. Accordingly, the initialization voltage VINT may be provided to the third transistor T3 of the third sub-pixel circuit.

The seventh gate pattern 2170 may extend in the first direction DR1 and may be spaced apart from the sixth gate pattern 2160. The driving voltage ELVDD may be provided to the seventh gate pattern 2170.

Although not illustrated in FIG. 11, the first conductive layer CL1′ may further include an eighth gate pattern extending in the first direction DR1. The common voltage ELVSS may be provided to the eighth gate pattern.

Referring further to FIG. 12, the protection layer (for example, the protection layer PVX of FIG. 9) may be disposed on the first conductive layer CL1′, and the via-insulating layer VIA may be disposed on the protection layer. A second conductive layer CL2′ may be disposed on the via-insulating layer VIA. The second conductive layer CL2′ may include a driving voltage line 2210, a light emitting element connection electrode 2220, an initialization voltage line 2230, a common voltage line 2240, and data lines 2250. The driving voltage line 2210, the light emitting element connection electrode 2220, the initialization voltage line 2230, the common voltage line 2240, and the data lines 2250 may be disposed in the same layer and may include the same material.

The driving voltage line 2210 may extend in the second direction DR2. The driving voltage line 2210 may be connected to the seventh gate pattern 2170 through a contact hole. Accordingly, the driving voltage ELVDD may be provided to the driving voltage line 2210.

In an embodiment, the driving voltage line 2210 overlapping the N-th pixel circuit area PXA(N) may provide the driving voltage ELVDD to the first transistor T1 included in the N-th pixel circuit.

The driving voltage line 2210 may be connected to the (2-1)-th gate pattern 2121 through a contact hole. Accordingly, the driving voltage line 2210 may provide the driving voltage ELVDD to the (2-1)-th gate pattern 2121. For example, the driving voltage line 2210 may provide the driving voltage ELVDD to the first transistor T1 of the first sub-pixel circuit included in the N-th pixel circuit through the (2-1)-th gate pattern 2121.

The driving voltage line 2210 may be connected to the (2-2)-th gate pattern 2122 through a contact hole. Accordingly, the driving voltage line 2210 may provide the driving voltage ELVDD to the (2-2)-th gate pattern 2122. For example, the driving voltage line 2210 may provide the driving voltage ELVDD to the first transistor T1 of the second sub-pixel circuit included in the N-th pixel circuit through the (2-2)-th gate pattern 2122.

The driving voltage line 2210 may be connected to the (2-3)-th gate pattern 2123 through a contact hole. Accordingly, the driving voltage line 2210 may provide the driving voltage ELVDD to the (2-3)-th gate pattern 2123. For example, the driving voltage line 2210 may provide the driving voltage ELVDD to the first transistor T1 of the third sub-pixel circuit included in the N-th pixel circuit through the (2-3)-th gate pattern 2123.

The light emitting element connection electrode 2220 may provide the driving current to the light emitting element LD. For example, the light emitting element connection electrode 2220 may be referred to as an upper light emitting element connection electrode. The light emitting element connection electrode 2220 may include a first light emitting element connection electrode 2221, a second light emitting element connection electrode 2222, and a third light emitting element connection electrode 2223.

The first light emitting element connection electrode 2221 may be connected to the (3-1)-th gate pattern 2131 through a contact hole. Accordingly, the first light emitting element connection electrode 2221 may provide the first driving current to the light emitting element LD included in the first sub-pixel SPX1.

The second light emitting element connection electrode 2222 may be connected to the (3-2)-th gate pattern 2132 through a contact hole. Accordingly, the second light emitting element connection electrode 2222 may provide the second driving current to the light emitting element LD included in the second sub-pixel SPX2.

The third light emitting element connection electrode 2223 may be connected to the (3-3)-th gate pattern 2133 through a contact hole. Accordingly, the third light emitting element connection electrode 2223 may provide the third driving current to the light emitting element LD included in the third sub-pixel SPX3.

The initialization voltage line 2230 may extend in the second direction DR2 and may be spaced apart from the light emitting element connection electrode 2220. The initialization voltage VINT may be provided to the initialization voltage line 2230. The initialization voltage line 2230 may be connected to the (6-1)-th gate pattern 2161 and the (6-2)-th gate pattern 2162 through a contact hole. Accordingly, the initialization voltage VINT may be provided to the (6-1)-th gate pattern 2161 and the (6-2)-th gate pattern 2162.

The common voltage line 2240 may extend in the second direction DR2 and may be adjacent to the initialization voltage line 2230 in the first direction DR1. The common voltage ELVSS may be provided to the common voltage line 2240.

Each of the data lines 2250 may extend in the second direction DR2. The data lines 2250 may be spaced apart from the initialization voltage line 2230 in the first direction DR1 with the common voltage line 2240 disposed between the data lines 2250 and the initialization voltage line 2230. The data lines 2250 may include a first data line 2251, a second data line 2252, and a third data line 2253.

The red data voltage may be provided to the first data line 2251. The first data line 2251 may be connected to the (4-1)-th gate pattern 2141 through a contact hole. Accordingly, the red data voltage may be provided to the (4-1)-th gate pattern 2141.

The green data voltage may be provided to the second data line 2252. The second data line 2252 may be connected to the (4-2)-th gate pattern 2142 through a contact hole. Accordingly, the green data voltage may be provided to the (4-2)-th gate pattern 2142.

The blue data voltage may be provided to the third data line 2253. The third data line 2253 may be connected to the (4-3)-th gate pattern 2143 through a contact hole. Accordingly, the blue data voltage may be provided to the (4-3)-th gate pattern 2143.

As the data lines 2250 are spaced apart from the initialization voltage line 2230 in the first direction DR1 with the common voltage line 2240 disposed between the data lines 2250 and the initialization voltage line 2230, the formation of the parasitic capacitance between the initialization voltage line 2230 and the data lines 2250 may be reduced. For example, the common voltage line 2240 may be disposed between the initialization voltage line 2230 and the data lines 2250 to suppress the formation of the parasitic capacitance. Accordingly, the occurrence of horizontal crosstalk in the display device DD2 may be reduced, and the display quality of the display device DD2 may be improved.

Compared to the display device DD according to an embodiment, in the display device DD, the driving voltage line 1240 may suppress the formation of the parasitic capacitance, whereas in the display device DD2 according to an embodiment, the common voltage line 2240 may suppress the formation of the parasitic capacitance.

In an embodiment, the driving voltage line 2210, the common voltage line 2240, and the data lines 2250 may be disposed in an order of the common voltage line 2240, the data lines 2250, and the driving voltage line 2210 in the first direction DR1. Although not illustrated in FIG. 12, the driving voltage line 2210 overlapping the (N+1)-th pixel circuit area PXA(N+1) may be adjacent to the data lines 2250 overlapping the N-th pixel circuit area PXA(N) in the first direction DR1. For example, the driving voltage line 2210, the common voltage line 2240, and the data lines 2250 may be disposed in the first direction DR1 in an order of the common voltage line 2240, the first data line 2251, the third data line 2253, the second data line 2252, and the driving voltage line 2210 overlapping the (N+1)-th pixel circuit area PXA(N+1).

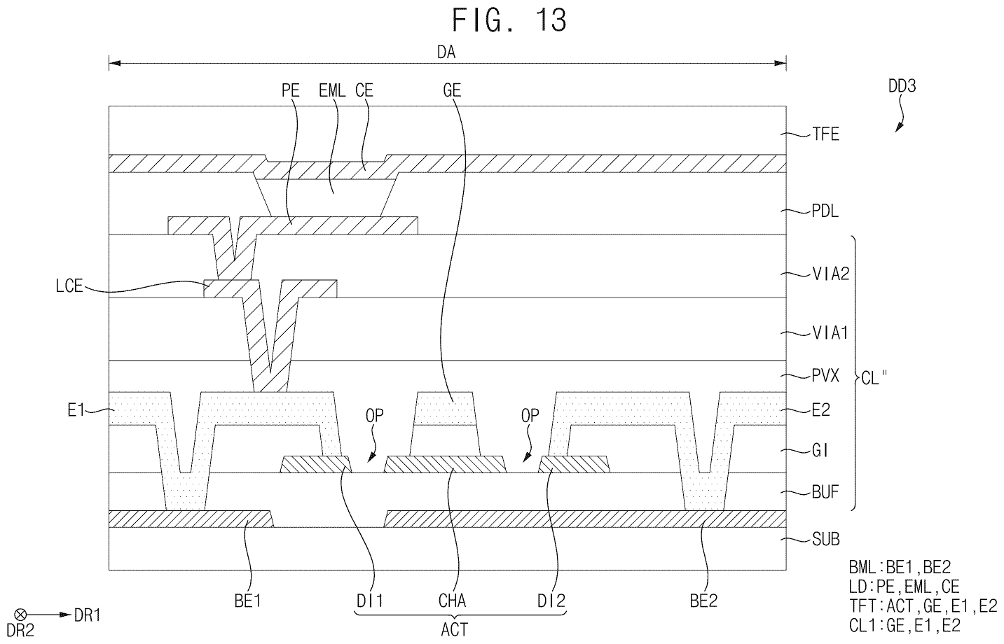

FIG. 13 is a schematic cross-sectional view illustrating a display device according to an embodiment.

Referring to FIG. 13, a display device DD3 according to an embodiment may include the substrate SUB, a circuit layer CL″, the light emitting element LD, the pixel defining layer PDL, and the encapsulation layer TFE. The circuit layer CL″ may include the lower electrode layer BML, the buffer layer BUF, the active pattern ACT, the gate insulating layer GI, the first conductive layer CL1, the protection layer PVX, a first via-insulating layer VIA1, a connection electrode LCE, and a second via-insulating layer VIA2. The lower electrode layer BML may include the first lower electrode BE1 and the second lower electrode BE2. The first conductive layer CL1 may include the first electrode E1, the second electrode E2, and the gate electrode GE. The light emitting element LD may include the pixel electrode PE, the light emitting layer EML, and the common electrode CE. Hereinafter, descriptions overlapping descriptions of the display device DD described with reference to FIGS. 1 to 4 will be omitted or simplified.

The first via-insulating layer VIA1 may be disposed on the protection layer PVX. The first via-insulating layer VIA1 may include an organic insulating material. The connection electrode LCE may be disposed on the first via-insulating layer VIA1. The connection electrode LCE may be electrically connected to the first electrode E1 through a contact hole penetrating the first via-insulating layer VIA1 and the protection layer PVX. Accordingly, the connection electrode LCE may electrically connect the thin film transistor TFT and the light emitting element LD. For example, the connection electrode LCE may include a metal, an alloy, a metal nitride, a conductive metal oxide, a transparent conductive material, etc. These may be used alone or in combination with each other.

The second via-insulating layer VIA2 may be disposed on the first via-insulating layer VIA1. The second via-insulating layer VIA2 may cover the connection electrode LCE. The second via-insulating layer VIA2 may include an organic insulating material.

The pixel electrode PE may be disposed on the second via-insulating layer VIA2. The pixel electrode PE may be connected to the connection electrode LCE through a contact hole penetrating the second via-insulating layer VIA2.

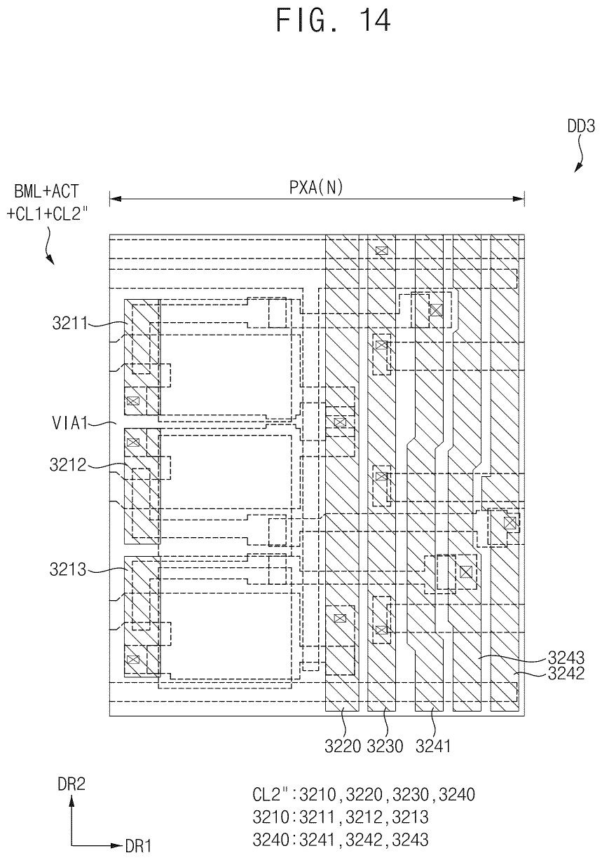

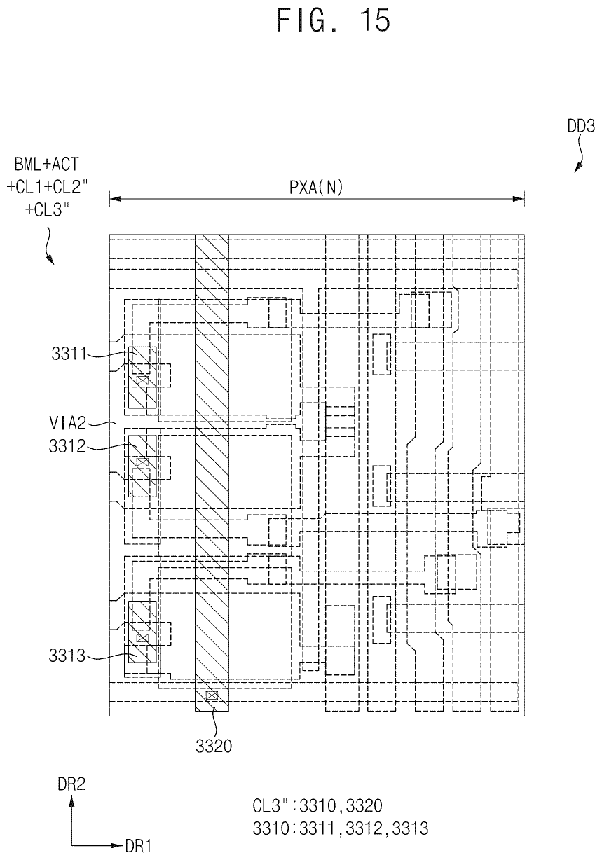

FIGS. 14 and 15 are schematic plan views illustrating a pixel included in the display device of FIG. 13. For example, FIGS. 14 and 15 are schematic plan views illustrating the circuit layer CL″ of FIG. 13. Hereinafter, the description will focus on the N-th pixel circuit disposed in the N-th pixel circuit area PXA(N). At least some of the components illustrated in FIGS. 14 and 15 may be interconnected between the pixel circuits.

In FIG. 14, a notation BML+ACT+CL1+CL2″ means that the lower electrode layer BML, the active pattern ACT disposed on the lower electrode layer BML, the first conductive layer CL1 disposed on the active pattern ACT, and a second conductive layer CL2″ disposed on the first conductive layer CL1 are illustrated. The second conductive layer CL2″ is illustrated by hatching, and components disposed under the second conductive layer CL2″ are illustrated by dotted lines.

In FIG. 15, a notation BML+ACT+CL1+CL2″+CL3″ means that the lower electrode layer BML, the active pattern ACT disposed on the lower electrode layer BML, the first conductive layer CLI disposed on the active pattern ACT, the second conductive layer CL2″ disposed on the first conductive layer CL1, and a third conductive layer CL3″ disposed on the second conductive layer CL2″ are illustrated. The third conductive layer CL3″ is illustrated by hatching, and components disposed under the third conductive layer CL3″ are illustrated by dotted lines.

The display device DD3 may be substantially the same as the display device DD described with reference to FIGS. 5 to 8, except that the display device DD3 may further include a third conductive layer CL3″ disposed on the second conductive layer CL2″, the second conductive layer CL2″ may include a driving voltage line 3230, and the third conductive layer CL3″ may include a common voltage line 3320.

For example, the lower electrode layer BML of the display device DD3 may be substantially the same as the lower electrode layer BML of the display device DD illustrated in FIG. 5. The active pattern ACT of the display device DD3 may be substantially the same as the active pattern ACT of the display device DD illustrated in FIG. 6. The first conductive layer CL1 of the display device DD3 may be substantially the same as the first conductive layer CL1 of the display device DD illustrated in FIG. 7. Hereinafter, descriptions overlapping descriptions of the display device DD described with reference to FIGS. 5 to 7 will be omitted or simplified.

Referring to FIGS. 1, 3, 7, and 14, the protection layer may be disposed on the first conductive layer CL1, and the first via-insulating layer VIA1 may be disposed on the protection layer. The second conductive layer CL2″ may be disposed on the first via-insulating layer VIA1.

The second conductive layer CL2″ may include a first light emitting element connection electrode 3210, an initialization voltage line 3220, the driving voltage line 3230, and data lines 3240. The first light emitting element connection electrode 3210, the initialization voltage line 3220, the driving voltage line 3230, and the data lines 3240 may be disposed in the same layer and may include the same material.

The first light emitting element connection electrode 3210 may provide a driving current to the light emitting element LD. For example, the first light emitting element connection electrode 3210 may be referred to as an intermediate light emitting element connection electrode. The first light emitting element connection electrode 3210 may include a (1-1)-th light emitting element connection electrode 3211, a (1-2)-th light emitting element connection electrode 3212, and a (1-3)-th light emitting element connection electrode 3213.

The (1-1)-th light emitting element connection electrode 3211 may be connected to the (6-1)-th gate pattern 1161 of FIG. 7 through a contact hole. Accordingly, the (1-1)-th light emitting element connection electrode 3211 may provide a first driving current to the light emitting element LD included in the first sub-pixel SPX1.

The (1-2)-th light emitting element connection electrode 3212 may be connected to the (6-2)-th gate pattern 1162 of FIG. 7 through a contact hole. Accordingly, the (1-2)-th light emitting element connection electrode 3212 may provide a second driving current to the light emitting element LD included in the second sub-pixel SPX2.

The (1-3)-th light emitting element connection electrode 3213 may be connected to the (6-3)-th gate pattern 1163 of FIG. 7 through a contact hole. Accordingly, the (1-3)-th light emitting element connection electrode 3213 may provide a third driving current to the light emitting element LD included in the third sub-pixel SPX3.

The initialization voltage line 3220 may extend in the second direction DR2 and may be spaced apart from the first light emitting element connection electrode 3210. The initialization voltage VINT may be provided to the initialization voltage line 3220. The initialization voltage line 3220 may be connected to the (7-1)-th gate pattern 1171 and the (7-2)-th gate pattern 1172, which are illustrated in FIG. 7, through a contact hole. Accordingly, the initialization voltage VINT may be provided to the (7-1)-th gate pattern 1171 and the (7-2)-th gate pattern 1172 which are illustrated in FIG. 7.

The driving voltage line 3230 may extend in the second direction DR2 and may be adjacent to the initialization voltage line 3220 in the first direction DR1. The driving voltage line 3230 may be connected to the first gate pattern 1110 of FIG. 7 through a contact hole. Accordingly, the driving voltage ELVDD may be provided to the driving voltage line 3230.

In an embodiment, the driving voltage line 3230 overlapping the N-th pixel circuit area PXA(N) may provide the driving voltage ELVDD to the first transistor T1 included in the (N+1)-th pixel circuit.

The driving voltage line 3230 may be connected to the (5-1)-th gate pattern 1151, the (5-2)-th gate pattern 1152, and the (5-3)-th gate pattern 1153, which are illustrated in FIG. 7, through a contact hole. Accordingly, the driving voltage line 3230 may provide the driving voltage ELVDD to the (5-1)-th gate pattern 1151, the (5-2)-th gate pattern 1152, and the (5-3)-th gate pattern 1153 which are illustrated in FIG. 7.

Each of the data lines 3240 may extend in the second direction DR2. The data lines 3240 may be spaced apart from the initialization voltage line 3220 in the first direction DR1 with the driving voltage line 3230 disposed between the data lines 3240 and the initialization voltage line 3220. The data lines 3240 may include a first data line 3241, a second data line 3242, and a third data line 3243.

A red data voltage may be provided to the first data line 3241. The first data line 3241 may be connected to the (4-1)-th gate pattern 1141 of FIG. 7 through a contact hole. Accordingly, the red data voltage may be provided to the (4-1)-th gate pattern 1141 of FIG. 7.

A green data voltage may be provided to the second data line 3242. The second data line 3242 may be connected to the (4-2)-th gate pattern 1142 of FIG. 7 through a contact hole. Accordingly, the green data voltage may be provided to the (4-2)-th gate pattern 1142 of FIG. 7.

A blue data voltage may be provided to the third data line 3243. The third data line 3243 may be connected to the (4-3)-th gate pattern 1143 of FIG. 7 through a contact hole. Accordingly, the blue data voltage may be provided to the (4-3)-th gate pattern 1143 of FIG. 7.

As the data lines 3240 are spaced apart from the initialization voltage line 3220 in the first direction DR1 with the driving voltage line 3230 disposed between the data lines 3240 and the initialization voltage line 3220, the formation of the parasitic capacitance between the initialization voltage line 3220 and the data lines 3240 may be reduced. For example, the driving voltage line 3230 may be disposed between the initialization voltage line 3230 and the data lines 3240 to suppress the formation of the parasitic capacitance.

Referring further to FIG. 15, the second via-insulating layer VIA2 may be disposed on the second conductive layer CL2″, and the third conductive layer CL3″ may be disposed on the second via-insulating layer VIA2. The third conductive layer CL3″ may include a second light emitting element connection electrode 3310 and the common voltage line 3320. The second light emitting element connection electrode 3310 and the common voltage line 3320 may be disposed in the same layer and may include the same material.

The second light emitting element connection electrode 3310 may provide the driving current to the light emitting element LD. For example, the second light emitting element connection electrode 3310 may be referred to as an upper light emitting element connection electrode. The second light emitting element connection electrode 3310 may include a (2-1)-th light emitting element connection electrode 3311, a (2-2)-th light emitting element connection electrode 3312, and a (2-3)-th light emitting element connection electrode 3313.

The (2-1)-th light emitting element connection electrode 3311 may be connected to the (1-1)-th light emitting element connection electrode 3211 through a contact hole. Accordingly, the (2-1)-th light emitting element connection electrode 3311 may provide the first driving current to the light emitting element LD included in the first sub-pixel SPX1.

The (2-2)-th light emitting element connection electrode 3312 may be connected to the (1-2)-th light emitting element connection electrode 3212 through a contact hole. Accordingly, the (2-2)-th light emitting element connection electrode 3312 may provide the second driving current to the light emitting element LD included in the second sub-pixel SPX2.

The (2-3)-th light emitting element connection electrode 3313 may be connected to the (1-3)-th light emitting element connection electrode 3213 through a contact hole. Accordingly, the (2-3)-th light emitting element connection electrode 3313 may provide the third driving current to the light emitting element LD included in the third sub-pixel SPX3.

The common voltage line 3320 may extend in the second direction DR2 and may be spaced apart from the second light emitting element connection electrode 3310. The common voltage line 3320 may be connected to the eighth gate pattern 1180 of FIG. 7 through a contact hole. Accordingly, the common voltage ELVSS may be provided to the common voltage line 3320.

In an embodiment, the driving voltage line 3230 and the common voltage line 3320 may be disposed in different layers. For example, the second conductive layer CL2″ may include the driving voltage line 3230, and the third conductive layer CL3″ may include the common voltage line 3320.

Compared to the display device DD according to an embodiment, in the display device DD, the second conductive layer CL2 may include the common voltage line 1210 of FIG. 8, whereas in the display device DD3 according to embodiment, the third conductive layer CL3″ may include the common voltage line 3320. For example, in the display device DD3, the second conductive layer CL2 may not include the common voltage line 3320. Accordingly, the space utilization of the circuit layer CL″ may be relatively increased, so the resolution of the display device DD3 may be relatively increased.

The disclosure may be applied to various display devices. For example, the disclosure is applicable to various display devices such as display devices for vehicles, ships and aircraft, portable communication devices, display devices for exhibition or information transmission, medical display devices, and the like within the spirit and the scope of the disclosure.

The foregoing is illustrative of embodiments of the disclosure, and is not to be construed as limiting thereof. Although a few embodiments have been described with reference to the figures, those skilled in the art will readily appreciate that many variations and modifications may be made therein without departing from the spirit and scope of the disclosure and as defined in the appended claims.

What is claimed is:

1. A display device comprising:
a substrate including first to N-th pixel circuit areas disposed in a first direction, where Nis a natural number greater than 1;
an initialization voltage line disposed on the substrate, the initialization voltage line extending in a second direction intersecting the first direction, and overlapping one of the first to N-th pixel circuit areas;
a driving voltage line disposed on the substrate, the driving voltage line extending in the second direction, and adjacent to the initialization voltage line in the first direction; and
a data line disposed on the substrate, the data line extending in the second direction, and spaced apart from the initialization voltage line in the first direction with the driving voltage line disposed between the data line and the initialization voltage line.

2. The display device of claim 1, further comprising:
first to N-th pixel circuits disposed in the first to N-th pixel circuit areas, respectively, wherein each of the first to N-th pixel circuits includes:
a driving transistor which provides a driving current;
a first switching transistor which provides a data voltage to the driving transistor; and
a second switching transistor which provides an initialization voltage to the driving transistor.

3. The display device of claim 2, wherein a gate electrode of the first switching transistor and a gate electrode of the second switching transistor receive a same signal.

4. The display device of claim 2, wherein
the driving voltage line overlaps each of the first to N-th pixel circuit areas, and
the driving voltage line overlapping the (N-1)-th pixel circuit area provides a driving voltage to the driving transistor included in the N-th pixel circuit.

5. The display device of claim 1, further comprising:
a common voltage line disposed on the substrate, the common voltage line extending in the second direction,
wherein the common voltage line, the driving voltage line, and the data line are disposed in the first direction in an order of the driving voltage line, the data line, and the common voltage line.

6. The display device of claim 5, wherein the driving voltage line and the common voltage line are disposed in a same layer.

7. The display device of claim 5, wherein the driving voltage line and the common voltage line are disposed in different layers.

8. The display device of claim 5, further comprising:
an active pattern disposed on the substrate and overlapping the first to N-th pixel circuit areas;
a first conductive layer disposed on the active pattern and including a gate electrode; and
a second conductive layer disposed on the first conductive layer.

9. The display device of claim 8, wherein the second conductive layer includes the driving voltage line and the common voltage line.

10. The display device of claim 8, further comprising:
a third conductive layer disposed on the second conductive layer, wherein
the second conductive layer includes the driving voltage line, and
the third conductive layer includes the common voltage line.

11. The display device of claim 8, wherein the active pattern includes an oxide semiconductor.

12. A display device comprising:
a substrate including first to N-th pixel circuit areas disposed in a first direction, where N is a natural number greater than 1;
an initialization voltage line disposed on the substrate, the initialization voltage line extending in a second direction intersecting the first direction, and overlapping one of the first to N-th pixel circuit areas;
a common voltage line disposed on the substrate, the common voltage line extending in the second direction, and adjacent to the initialization voltage line in the first direction, and
a data line disposed on the substrate, the data line extending in the second direction, and spaced apart from the initialization voltage line in the first direction with the common voltage line disposed between the data line and the initialization voltage line.

13. The display device of claim 12, further comprising:
first to N-th pixel circuits disposed in the first to N-th pixel circuit areas, respectively, wherein each of the first to N-th pixel circuits includes:
a driving transistor which provides a driving current;
a first switching transistor which provides a data voltage to the driving transistor; and
a second switching transistor which provides an initialization voltage to the driving transistor.

14. The display device of claim 13, wherein a gate electrode of the first switching transistor and a gate electrode of the second switching transistor receive a same signal.

15. The display device of claim 13, further comprising:
a driving voltage line disposed on the substrate and extending in the second direction,
wherein the driving voltage line, the common voltage line, and the data line are disposed in the first direction in an order of the common voltage line, the data line, and the driving voltage line.

16. The display device of claim 15, wherein
the driving voltage line overlaps each of the first to N-th pixel circuit areas, and
the driving voltage line overlapping the N-th pixel circuit area provides a driving voltage to the driving transistor included in the N-th pixel circuit.

17. The display device of claim 15, wherein the driving voltage line and the common voltage line are disposed in a same layer.

18. The display device of claim 15, further comprising:
an active pattern disposed on the substrate and overlapping the first to N-th pixel circuit areas;
a first conductive layer disposed on the active pattern and including a gate electrode; and
a second conductive layer disposed on the first conductive layer.

19. The display device of claim 18, wherein the second conductive layer includes the driving voltage line and the common voltage line.
